(19) United States
(12) Patent Application Publication
(10) Pub. No.: US 2025/0257263 A1
(43) Pub. Date: Aug. 14, 2025

(54) SEMICONDUCTOR NANOPARTICLE, PRODCUTION METHOD THEREOF, ELECTRONIC DEVICE INCLUDING THE SAME

(71) Applicant: Samsung Electronics Co., Ltd., Suwon-si (KR)

(72) Inventors: Min Jong BAE, Suwon-si (KR); A Ra JO, Suwon-si (KR); Sue In Chae, Suwon-si (KR); Nayoun WON, Suwon-si (KR); Taekhoon KIM, Suwon-si (KR); Jun Ho LEE, Suwon-si (KR); Tae-Gon KIM, Suwon-si (KR)

(21) Appl. No.: 19/048,366

(22) Filed: Feb. 7, 2025

(30) Foreign Application Priority Data
Feb. 8, 2024 (KR) 10-2024-0019937

(51) Int. Cl. C09K 11/88; B82Y 20/00; B82Y 30/00; B82Y 40/00; C01G 15/00; C09D 11/037; C09D 11/322; C09D 11/50; C09D 11/52; C09K 11/02; C09K 11/62; G02F 1/13357; H10H 29/85; H10K 59/38

(52) U.S. Cl. CPC C09K 11/881; C01G 15/006; C09D 11/037; C09D 11/322; C09D 11/50; C09D 11/52; C09K 11/025; C09K 11/621; B82Y 20/00; B82Y 30/00; B82Y 40/00; C01P 2002/84; C01P 2004/04; C01P 2004/64; C01P 2006/60; G02F 1/133617; G02F 2202/36; H10H 29/8517; H10K 59/38

(57) ABSTRACT

A semiconductor nanoparticle, a method of producing the semiconductor nanoparticle, and an electronic device including the semiconductor nanoparticle. The semiconductor nanoparticle includes silver, indium, gallium, and sulfur, with a molar ratio of gallium to indium (Ga/In) of greater than or equal to about 0.8:1 and less than or equal to about 20:1. The semiconductor nanoparticle is substantially free of copper and is configured to emit red light. The emission peak wavelength of the red light is greater than or equal to about 600 nm and less than or equal to about 650 nm, with a full width at half maximum (FWHM) of greater than or equal to about 5 nm and less than or equal to about 90 nm.

### CROSS-REFERENCE TO RELATED APPLICATION

This application is based on and claims priority to Korean Patent Application No. 10-2024-0019937 filed in the Korean Intellectual Property Office on Feb. 8, 2024, and all the benefits accruing therefrom under 35 U.S.C. § 119, the entire content of which is incorporated herein by reference.

### BACKGROUND

### 1. Field

A semiconductor nanoparticle, a method of producing the semiconductor nanoparticle, and an electronic device including the semiconductor nanoparticle are disclosed,

### 2. Description of the Related Art

A semiconductor nanoparticle may exhibit different aspects, characteristics, or properties compared to a corresponding bulk material having substantially the same composition. For example, the semiconductor nanoparticle may have different physical properties based on the nanostructure (e.g., energy bandgap, a luminescent property, or the like). The semiconductor nanoparticle may be configured to emit light upon excitation by incident light or an applied voltage. The luminescent nanostructure may find applicability in a variety of devices (e.g., a display panel or an electronic device including the display panel). From an environmental point of view, developing a luminescent nanoparticle that does not contain a harmful heavy metal, such as cadmium, and yet achieving an improvement in one or more luminescent or optical properties is desirable.

### SUMMARY

An aspect relates to a red light-emitting cadmium-free semiconductor nanoparticle exhibiting enhanced absorption.

An aspect relates to a method of manufacturing the semiconductor nanoparticle.

An aspect relates to a composition (e.g., an ink composition) including the semiconductor nanoparticle,

An aspect relates to a color conversion panel including the semiconductor nanoparticle,

An aspect relates to an electronic device (e.g., a display device) including the semiconductor nanoparticle or the color conversion panel.

In an embodiment, a semiconductor nanoparticle includes silver, indium, gallium, and sulfur. The semiconductor nanoparticle is substantially free of copper. A molar ratio of gallium to indium is greater than or equal to about 0.8:1, for example, greater than 1:1 and less than or equal to about 20:1. The semiconductor nanoparticle is configured to emit a red light. A peak emission wavelength of the red light is greater than or equal to about 600 nm and less than or equal to about 650 nm. A full width at half maximum (FWHM) of the red light is greater than or equal to about 5 nm and less than or equal to about 90 nm, or less than or equal to about 84 nm. The FWHM of the red light may be greater than or equal to about 10 nm and less than or equal to about 50 nm. In the semiconductor nanoparticle, a mole ratio of gallium to indium (Ga:In) may be greater than or equal to about 0.8:1, or greater than or equal to about 1:1 and less than or equal to about 3.5:1. In the semiconductor nanoparticle, the mole ratio of gallium to indium (Ga:In) may be greater than or equal to about 1.1:1, greater than or equal to about 1.3:1, greater than or equal to about 1.5:1, or greater than or equal to about 2:1 and less than or equal to about 15:1, or less than or equal to about 10:1.

The semiconductor nanoparticle may include a group 11-13-16 compound including silver, indium, gallium, and sulfur. The semiconductor nanoparticle may include a first semiconductor nanocrystal including silver, indium, gallium, and sulfur, and a second semiconductor nanocrystal including gallium and sulfur. The semiconductor nanoparticle may include a first semiconductor nanocrystal including silver, indium, sulfur, and optionally selenium, and a second semiconductor nanocrystal including gallium, sulfur, and optionally silver. The semiconductor nanoparticle has a core-shell structure having a core including the first semiconductor nanocrystal; and a shell including the second semiconductor nanocrystal and being disposed on the core. The shell or the second semiconductor nanocrystal further comprising selenium.

In an embodiment, the semiconductor nanoparticle may further include or may not include zinc, copper, or a combination thereof.

In an embodiment, the semiconductor nanoparticle may further include a semiconductor nanocrystal (e.g., an additional semiconductor nanocrystal) containing zinc, sulfur, and optionally gallium (e.g., a third semiconductor nanocrystal or a fourth semiconductor nanocrystal).

In the semiconductor nanoparticle, a mole ratio of silver to indium (Ag:In) may be greater than or equal to about 0.5:1, greater than or equal to about 1:1, greater than or equal to about 1.1:1, or greater than or equal to about 1.5:1, and less than or equal to about 2.8:1, less than or equal to about 2.5:1, or less than or equal to about 2:1.

In the semiconductor nanoparticle, a mole ratio of a total sum of indium and gallium to silver [(In+Ga):Ag] may be greater than or equal to about 1.5:1, greater than or equal to about 1.7:1, or greater than or equal to about 2:1 and less than or equal to about 3.5:1, less than or equal to about 3:1, less than or equal to about 2.7:1, or less than or equal to about 2.2:1.

In the semiconductor nanoparticle, a mole ratio of indium to sulfur (In:S) may be greater than or equal to about 0.13:1, or greater than or equal to about 0.19:1 and less than or equal to about 0.5:1, or less than or equal to about 0.25:1.

In the semiconductor nanoparticle, a mole ratio of sulfur to indium (S:In) may be greater than or equal to about 2:1, or greater than or equal to about 3.2:1 and less than or equal to about 10:1, or less than or equal to about 7.7:1.

In the semiconductor nanoparticle, a mole ratio of gallium to sulfur (Ga:S) may be greater than or equal to about 0.29:1, greater than or equal to about 0.48:1, or greater than or equal to about 0.5:1 and less than or equal to about 0.9:1, or less than or equal to about 0.8:1.

In the semiconductor nanoparticle, a mole ratio of a total sum of indium and gallium to sulfur [(In+Ga):S] may be greater than or equal to about 0.54:1, greater than or equal to about 0.56:1, greater than or equal to about 0.7:1, or greater than or equal to about 0.9:1 and less than or equal to about 1.5:1, less than or equal to about 1.1:1, or less than or equal to about 1:1.

In the semiconductor nanoparticle, a mole ratio of silver to sulfur (Ag:S) may be greater than or equal to about 0.25:1, or greater than or equal to about 0.3:1 and less than or equal to about 0.5:1, or less than or equal to about 0.45:1.

In the semiconductor nanoparticle, a mole ratio of silver to a sum of silver, indium, and gallium [Ag:(Ag+In+Ga)] may be greater than or equal to about 0.2:1, greater than or equal to about 0.3:1 and less than or equal to about 0.45:1, or less than or equal to about 0.40:1.

In the semiconductor nanoparticle, a mole ratio of gallium to a sum of silver, indium, and gallium [Ga:(Ag+In+Ga)] may be greater than or equal to about 0.32:1, greater than or equal to about 0.33:1, and less than or equal to about 0.6:1, less than or equal to about 0.55:1, or less than or equal to about 0.49:1.

In the semiconductor nanoparticle, a mole ratio of sulfur to a sum of silver, indium, and gallium [S:(Ag+In+Ga)] may be greater than or equal to about 0.7:1, or greater than or equal to about 0.9:1 and less than or equal to about 1.2:1, less than or equal to about 1.14:1.

The semiconductor nanoparticle, the first semiconductor nanocrystal, or the second semiconductor nanocrystal may further include selenium. If present, a mole ratio of selenium to indium in the semiconductor nanoparticle may be greater than or equal to about 0.001:1, greater than or equal to about 0.005:1, greater than or equal to about 0.01:1, greater than or equal to about 0.05:1, greater than or equal to about 0.08:1, greater than or equal to about 0.09:1, or greater than or equal to about 0.1:1. In the semiconductor nanoparticle, the mole ratio of selenium to indium may be less than or equal to about 0.5:1, less than or equal to about 0.2:1, or less than or equal to about 0.15:1.

The semiconductor nanoparticle may have a quantum yield of greater than or equal to about 10% or greater than or equal to about 30%. The peak emission wavelength of the first light or the semiconductor nanoparticle may be greater than or equal to about 602 nm and less than or equal to about 645 nm.

The full width at half maximum (FWHM) of the light or the semiconductor nanoparticle may be greater than or equal to about 15 nm and less than or equal to about 84 nm, less than or equal to about 70 nm, less than or equal to about 49 nm, or less than or equal to about 48 nm.

The semiconductor nanoparticle may have an optical density (e.g., at 450 nm) per a weight (unit: liters per gram per centimeter (L*g⁻¹*cm⁻¹) or milliliters per milligram per centimeter (mL*mg⁻¹*cm⁻¹) of greater than or equal to about 0.8 and less than or equal to about 4 in ultraviolet-visible (UV-Vis) absorption spectroscopy.

The semiconductor nanoparticle may have an optical density (e.g., at 450 nm) per a weight (unit: L*g⁻¹*cm⁻¹ or mL*mg⁻¹*cm⁻¹) of greater than or equal to about 2 and less than or equal to about 3.5 in UV-Vis absorption spectroscopy.

The semiconductor nanoparticle may have a ratio of absorption at 550 nanometers (nm) to absorption at 350 nm that is greater than or equal to about 0.05:1 and less than or equal to about 0.5:1 in UV-Vis absorption spectroscopy.

In an embodiment, a method of manufacturing the semiconductor nanoparticle includes:
contacting a silver precursor, a first sulfur precursor, and an indium precursor in a first reaction medium, comprising a first organic solvent and heating the first reaction medium to a reaction temperature to prepare a first semiconductor nanocrystal comprising silver, indium, and sulfur, wherein an amount of the first sulfur precursor is greater than or equal to about 2.5 moles and less than or equal to about 20 moles per mole of the indium precursor; and
contacting (e.g., reacting) a second sulfur precursor, the first semiconductor nanocrystal, and a gallium precursor in a second reaction medium, comprising a second organic solvent.

In the method, an amount of the first sulfur precursor may be greater than or equal to about 4 moles and less than or equal to about 8 moles per mole of the indium precursor.

The predetermined temperature may be greater than about 210° C., or greater than or equal to about 230° C. and less than or equal to about 300° C., or less than or equal to about 260° C.

In the method, the first reaction medium may further include an organic ligand.

In an embodiment, an ink composition may include the semiconductor nanoparticle and a liquid vehicle. The liquid vehicle may include a polymerizable monomer, an organic solvent, or a combination thereof. The ink composition may further include or may be substantially free of a volatile organic solvent. The ink composition may further include a metal oxide nanoparticle.

In an embodiment, a semiconductor nanoparticle-polymer composite may include a polymer matrix and the semiconductor nanoparticle dispersed within the polymer matrix.

An aspect provides a color conversion layer or a color conversion structure (hereinafter, can be referred to as color conversion layer) including a color conversion region including the aforementioned semiconductor nanoparticles. In an embodiment, a color conversion panel may include a color conversion layer including a color conversion region and optionally a partition wall defining each region of the color conversion layer, The color conversion region (e.g., a black matrix, bank, pixel defining layer) may include a first region corresponding to the first pixel, The first region may include a first composite, and the first composite may include a matrix and a semiconductor nanoparticle dispersed in the matrix, wherein the first region is configured to emit a first light.

An embodiment relates to a display device (or display panel) including a light source and the semiconductor nanoparticle (or a composite, color conversion layer, color conversion panel, etc. including the semiconductor nanoparticle). In an embodiment, the display panel may include a light-emitting panel (or light source), the color conversion panel, and optionally a light-transmitting layer positioned between the light-emitting panel and the color conversion panel.

The light-emitting panel (or a light source) may be configured to provide incident light to the color conversion layer (or color conversion panel). The incident light may include a blue light and optionally a green light. The blue light may have a peak emission wavelength in the range of 440 nm to 460 nm or 450 nm to 455 nm.

The light source may include an organic light-emitting diode, a micro LED, a mini LED, a nanorod-containing LED, or a combination thereof.

In an embodiment, an electronic device (or display device) may include the color conversion panel or the display panel.

In an embodiment, the display device may include a display device for augmented reality/virtual reality devices, a mobile terminal device, a monitor, a laptop, a television, an electronic signboard, a camera, an automotive electronic component, or the like.

The semiconductor nanoparticle of an embodiment can be utilized as a light-emitting material in a color conversion pixel due to its ability to emit red light while achieving enhanced light absorption and a narrow full width at half maximum (FWHM).

### BRIEF DESCRIPTION OF THE DRAWINGS

The above and other aspects, features, and advantages of certain exemplary embodiments will be more apparent from the following detailed description taken in conjunction with the accompanying drawings.

FIG. 1A is a flowchart showing a pattern formation process (photolithography method) using the ink composition of an embodiment.

FIG. 1B is a flowchart showing a pattern forming process (inkjet method) using the ink composition of an embodiment.

FIG. 2A is a schematic cross-sectional view of a color conversion panel according to an embodiment.

FIG. 2B is a cross-sectional view of an electronic device (display device) including a color conversion panel according to an embodiment.

FIG. 3A is a perspective view illustrating an example of a display panel including a color conversion panel according to an embodiment.

FIG. 3B is an exploded view of a display device according to an embodiment,

FIG. 3C is a cross-sectional view of the display panel of FIG. 3A.

FIG. 4 is an exploded view of a display device according to an embodiment.

FIG. 5A is a plan view illustrating an example of a pixel arrangement of the display panel of FIG. 3A.

FIGS. 5B, 5C, 5D, and 5E are cross-sectional views showing examples of light emitting devices, respectively, according to an embodiment.

FIG. 6 is a cross-sectional view of the display panel of FIG. 5A taken along line IV-IV.

FIG. 7A is a schematic cross-sectional view of a display device (e.g., a liquid crystal display device) according to an embodiment.

FIG. 7B is a schematic cross-sectional view of an electronic device (e.g., a light emitting device) according to an embodiment.

FIG. 8 a graph illustrating absorbance (arbitrary unit, a.u.) versus wavelength (nanometers, nm) of the UV-Vis absorption spectra of semiconductor nanoparticles prepared in Examples 1, 2, and 3.

FIG. 9 is a transmission electron microscopy (TEM) analysis image of the semiconductor nanoparticles synthesized in Example 1.

FIG. 10 is a TEM analysis image of the semiconductor nanoparticles synthesized in Example 2.

### DETAILED DESCRIPTION

Advantages and features of the techniques described hereinafter, and methods of achieving them, will become apparent with reference to the exemplary embodiments described below in further detail in conjunction with the accompanying drawings, However, the embodiments should not be construed as being limited to the exemplary embodiments set forth herein, If not defined otherwise, all terms (including technical and scientific terms) as used herein may be defined as commonly understood by one having ordinary skill in the art, The terms defined in a generally-used dictionary may not be interpreted ideally or exaggeratedly unless clearly defined, In addition, unless explicitly described to the contrary, the word “comprise” and variations such as “comprises” or “comprising,” will be understood to imply the inclusion of stated elements but not the exclusion of any other elements, In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it can be directly on the other element or intervening elements may also be present, In contrast, when an element is referred to as being “directly on” another element, there are no intervening elements present.

As used herein, the singular forms “a,” “an,” and “the” are intended to include the plural forms, including “at least one,” unless the context clearly indicates otherwise. For example, the wording “semiconductor nanoparticle” may refer to a single semiconductor nanoparticle or may refer to a plurality of semiconductor nanoparticles. “At least one” is not to be construed as being limited to “a” or “an.” “Or” means “and/or.” As used herein, the term “and/or” includes any and all combinations of one or more of the associated listed items.

It will be understood that, although the terms “first,” “second,” “third” etc. may be used herein to describe various elements, components, regions, layers, and/or sections, these elements, components, regions, layers, and/or sections should not be limited by these terms, These terms are only used to distinguish one element, component, region, layer, or section from another element, component, region, layer, or section, Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments, As such, variations from the shapes of the illustrations as a result, for example, of manufacturing techniques and/or tolerances, are to be expected, Thus, embodiments described herein should not be construed as limited to the particular shapes of regions as illustrated herein but are to include deviations in shapes that result, for example, from manufacturing, For example, a region illustrated or described as flat may, typically, have rough and/or nonlinear features, Moreover, sharp angles that are illustrated may be rounded, Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system), For example, “about” can mean within one or more standard deviations, or within ±10%, 5%, or ±3% of the stated value.

As used herein, the expression “not including cadmium (or other harmful heavy metal)”, or “cadmium-free” may refer to the case in which a concentration of cadmium (or other harmful heavy metal) may be less than or equal to about 1000 parts per million by weight (ppmw), less than or equal to about 100 ppmw, less than or equal to about 50 ppmw, less than or equal to about 10 ppmw, less than or equal to about 1 ppmw, less than or equal to about 0.1 ppmw, less than or equal to about 0.01 ppmw, or zero, In an embodiment, substantially no amount of cadmium (or other harmful heavy metal) may be present or, if present, an amount of cadmium (or other harmful heavy metal) may be less than or equal to a detection limit or as an impurity level of a given analysis tool.

As used herein, the expression “substantially free of” a substance (e.g., copper, other metal, or a solvent) means that a concentration of the substance may be less than or equal to about 1000 parts per million by weight (ppmw), less than or equal to about 100 ppmw, less than or equal to about 50 ppmw, less than or equal to about 10 ppmw, less than or equal to about 1 ppmw, less than or equal to about 0.1 ppmw, less than or equal to about 0.01 ppmw, or zero, In an embodiment, substantially free of the substance means that no amount of the substance may be present or, if present, an amount of the substance may be less than or equal to a detection limit or as an impurity level of a given analysis tool.

Hereinafter, as used herein, when a definition is not otherwise provided, “substituted” refers to replacement of at least one hydrogen of a compound or a moiety by a substituent selected from a C1 to C30 alkyl group, a C2 to C30 alkenyl group, a C2 to C30 alkynyl group, a C6 to C30 aryl group, a C7 to C30 alkylaryl group, a C7 to C30 arylalkyl group, a C6 to C30 aryloxy group, a C6 to C30 arylthio group, a C1 to C30 alkoxy group, a C1 to C30 alkylthio group, a C1 to C30 heteroalkyl group, a C3 to C30 heteroalkylaryl group, a C2 to C30 alkylheteroaryl group, a C2 to C30 heteroarylalkyl group, a C1 to C30 heteroaryloxy group, a C1 to C30 heteroarylthio group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group or an amine group (—NRR′ wherein R and R′ are each independently hydrogen or a C1 to C6 alkyl group), an azido group (═N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation, a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof. In addition, when a definition is not otherwise provided below, “hetero” means a case including 1 to 3 heteroatoms selected from N, O, P, Si, S, Se, Ge, and B.

In addition, the term “aliphatic hydrocarbon group” as used herein refers to a C1 to C30 linear or branched alkyl group, a C2 to C30 linear or branched alkenyl group, or a C2 to C30 linear or branched alkynyl group, and the term “aromatic organic group” as used herein refers to a C6 to C30 aryl group or a C2 to C30 heteroaryl group.

As used herein, the term “(meth)acrylate” refers to acrylate and/or methacrylate.

As used herein, the term “Group” refers to a Group of Periodic Table.

As used herein, the terms “a nanoparticle” and “a nanostructure” refer to a structure having at least one region or characteristic dimension with a nanoscale dimension. In an embodiment, the dimension of the nanoparticle or the nanostructure may be less than about 500 nm, less than about 300 nm, less than about 250 nm, less than about 150 nm, less than about 100 nm, less than about 50 nm, or less than about 30 nm, The nanoparticle or nanostructure may have any shape, such as a nanowire, a nanorod, a nanotube, a multi-pod type shape having two or more pods, a nanodot, or the like, but embodiments are not limited thereto. The nanoparticle or nanostructure may be, for example, substantially crystalline, substantially monocrystalline, polycrystalline, amorphous, or a combination thereof.

A quantum dot may be, for example, a semiconductor-containing nanocrystal particle that can exhibit a quantum confinement or exciton confinement effect, and is a type of a luminescent nanostructure (e.g., capable of emitting light by energy excitation). Herein, a shape of the “quantum dot” or the nanoparticle is not limited unless otherwise expressly defined.

As used herein, the term “dispersion” refers to a dispersion in which a dispersed phase is a solid, and a continuous medium includes a liquid or a solid different from the dispersed phase, It is to be understood that the “dispersion” may be a colloidal dispersion in which the dispersed phase has a dimension of greater than or equal to about 1 nm, for example, greater than or equal to about 2 nm, greater than or equal to about 3 nm, or greater than or equal to about 4 nm and several micrometers (μm) or less, (e.g., less than or equal to about 2 μm, less than or equal to about 1 μm, less than or equal to about 900 nm, less than or equal to about 800 nm, less than or equal to about 700 nm, less than or equal to about 600 nm, or less than or equal to about 500 nm.

Herein, a dimension (a size, a diameter, or a thickness, etc.) may be a value for a single entity or an average value for a plurality of nanoparticles. As used herein, the term “average” (e.g., an average size of the quantum dot) may be a mean value or a median value, In an embodiment, the average may be “mean” average.

As used herein, the term “peak emission wavelength” (or emission peak wavelength) is the wavelength at which a given emission spectrum of the light reaches its maximum.

In an embodiment, a quantum efficiency may be readily and reproducibly determined using commercially available equipment (e.g., from Hitachi or Hamamatsu, etc.) and referring to manuals provided by, for example, respective equipment manufacturers, The quantum efficiency (which can be interchangeably used with the term “quantum yield” (QY)) may be measured in a solution state or a solid state (i.e., in a composite). In an embodiment, the quantum efficiency (or the quantum yield) is the ratio of photons emitted to photons absorbed by the nanostructure or population thereof. In an embodiment, the quantum efficiency may be measured by any method. For example, there may be two methods for measuring the fluorescence quantum yield or efficiency: the absolute method and the relative method. The quantum efficiency measured by the absolute method may be referred to as an absolute quantum efficiency.

In the absolute method, the quantum efficiency may be obtained by detecting the fluorescence of all samples through an integrating sphere. In the relative method, the quantum efficiency of the unknown sample may be calculated by comparing the fluorescence intensity of a standard dye (a standard sample) with the fluorescence intensity of the unknown sample, Coumarin 153, Coumarin 545, Rhodamine 101 inner salt, Anthracene and Rhodamine 6G may be used as standard dyes according to their photoluminescence (PL) wavelengths, but embodiments are not limited thereto.

A full width at half maximum (FWHM) and a maximum emission (e.g., PL: photoluminescence or EL: electroluminescence) wavelength may be measured, for example, from a luminescence spectrum (for example, a photoluminescence spectrum or an electroluminescent spectrum) obtained by a spectrophotometer such as a fluorescence spectrophotometer or the like.

As used herein, the term “first absorption peak wavelength” refers to a wavelength at which a main peak first appears in a lowest energy region in the ultraviolet-visible (UV-Vis) absorption spectrum.

A semiconductor nanoparticle may be included in a variety of electronic devices. An electrical and/or an optical property of the semiconductor nanoparticle may be controlled for example, by the elemental composition of the semiconductor nanoparticle, the size of the semiconductor nanoparticle, and/or the shape of the semiconductor nanoparticle. In an embodiment, the semiconductor nanoparticle may be a semiconductor nanocrystal particle. The semiconductor nanoparticle such as a quantum dot may have a relatively large surface area per a unit volume, and thus, may exhibit a quantum confinement effect, exhibiting physical and/or optical properties different from a corresponding bulk material having the same composition. Therefore, a semiconductor nanoparticle such as a quantum dot may absorb energy (e.g., incident light) supplied from an excitation source to form an excited state, which upon relaxation is capable of emitting an energy corresponding to its energy bandgap.

The semiconductor nanoparticle can be used in various electronic devices, for example, in a color conversion panel (or an emissive color filter). It may include a white light-emitting backlight unit and an absorptive color filter of a liquid crystal display device, and the backlight unit may include a quantum dot sheet. In a display device including a quantum dot-based color conversion panel or an emissive color filter, the quantum dot layer, which is a light-emitting material, may be positioned at the front of the display device, and the blue light (excitation light) provided from the light source may be converted into green light or red light by the quantum dot layer. In the color conversion panel, the color conversion of the incident light can occur at the relatively front part of the display device, and a wide viewing angle can be achieved by the omnidirectional scattering of light. The emissive color filter can realize a reduction in light loss. The color conversion panel can be an electronic device including a color conversion layer or a color conversion structure.

In the display device including the color conversion panel, properties (e.g., an optical property, stability, or the like) of a luminescent material may have a direct effect on a displaying quality of the display device. It may be desired for the luminescent material included in the color conversion panel disposed at a relatively front part of the display device to exhibit not only a relatively high luminous efficiency but also a relatively high absorbance with respect to an incident light. When a patterned film (e.g., a color filter) is used in the display device, a decreased absorbance to the incident light may be a direct cause of a blue light leakage, having an adversely effect on a color reproducibility (e.g., DCI match rate) of the display device. An adoption of an absorption type color filter for preventing a blue light leakage problem may lead to an additional decrease in a luminous efficiency. Such a lowered absorbance of the semiconductor nanoparticle may result in a reduced luminance in a display device including the same.

Semiconductor nanoparticles may exhibit properties (e.g., optical properties and/or stability) that may be applicable to a display device, but many of them may include a cadmium-based compounds (e.g., a cadmium chalcogenide). The cadmium causes a serious environment/health problem and thus is one of the restricted elements in many countries. Therefore, in order to develop cadmium-free environment-friendly nanoparticles, an in-depth research on nanocrystals based on Group Ill-V compounds has been conducted. However, cadmium-free nanoparticles including a Group Ill-V compound (e.g., indium phosphide) may come across a technological limit in the incident light absorbance and the full width at half maximum. Accordingly, there remains a technological need to develop an environmentally friendly nanoparticle that can exhibit a higher absorbance, a narrower the full width at half maximum, and a higher luminous efficiency in comparison with a cadmium-free nanoparticle based on a Group Ill-V compound such as an indium phosphide.

In an embodiment, the semiconductor nanoparticle may not contain cadmium. The semiconductor nanoparticle may not contain mercury, lead, or a combination thereof. In an embodiment, the semiconductor nanoparticle may include (a group 11-13-16 compound including) silver, indium, gallium, and sulfur. The semiconductor nanoparticle may have a size or an average size (hereinafter referred to as size) of greater than or equal to about 5 nm, or greater than or equal to about 10 nm, and less than or equal to about 50 nm, less than or equal to about 25 nm, or less than or equal to about 20 nm.

In an embodiment, the semiconductor nanoparticle may include silver, indium, sulfur, and gallium. The semiconductor nanoparticle may include a first semiconductor nanocrystal including silver, indium, and sulfur (including a group 11-13-16 compound). The first semiconductor nanocrystal may further include or may not include zinc. The first semiconductor nanocrystal may further include or may not include copper. The first semiconductor nanocrystal may include or may not include gallium. The first semiconductor nanocrystal may further include or may not include selenium. In an embodiment, the first semiconductor nanocrystal may further include selenium.

The semiconductor nanoparticle may include a second semiconductor nanocrystal having a composition different from that of the first semiconductor nanocrystal, including gallium, sulfur, and optionally silver; additional semiconductor nanocrystals (e.g., a third semiconductor nanocrystal and/or a fourth semiconductor nanocrystal); or a combination thereof.

In an embodiment, the second semiconductor nanocrystal may include gallium and a chalcogen element (sulfur, and optionally selenium). The second semiconductor nanocrystal may include a Group 13-16 compound, a Group 11-13-16 compound, or a combination thereof. The Group 13-16 compound may include a gallium sulfide, a gallium selenide, a gallium selenide sulfide, an indium sulfide, an indium selenide, an indium gallium sulfide, an indium gallium selenide, an indium gallium selenide sulfide, or a combination thereof. The Group 11-13-16 compound may include a silver gallium sulfide, a silver gallium selenide, a silver gallium selenide sulfide, or a combination thereof. The second semiconductor nanocrystal may include gallium, sulfur, and selenium. The second semiconductor nanocrystal may include a ternary alloy semiconductor material including silver, gallium, and sulfur; a ternary alloy semiconductor material including indium, gallium, and sulfur; a ternary alloy semiconductor material including gallium, sulfur, and selenium; a ternary alloy semiconductor material including zinc, gallium, and sulfur; a quaternary alloy semiconductor material including silver, gallium, zinc, and sulfur; or a combination thereof.

An additional semiconductor nanocrystal may include zinc, sulfur, and optionally gallium. In an embodiment, the third semiconductor nanocrystal may include zinc, gallium, and sulfur. The fourth semiconductor nanocrystal may include zinc and sulfur. The third semiconductor nanocrystal may include zinc gallium sulfide. The fourth semiconductor nanocrystal may include zinc sulfide.

The second semiconductor nanocrystal may cover at least a portion of the first semiconductor nanocrystal. An energy bandgap of the second semiconductor nanocrystal may be different from that of the first semiconductor nanocrystal. The energy bandgap of the second semiconductor nanocrystal may be greater than that of the first semiconductor nanocrystal. The energy bandgap of the second semiconductor nanocrystal may be less than that of the first semiconductor nanocrystal. An energy bandgap of the additional semiconductor nanocrystal (e.g., the third semiconductor nanocrystal or the fourth semiconductor nanocrystal) may be greater than that of the second semiconductor nanocrystal. The energy bandgap of the additional semiconductor nanocrystal (e.g., the third semiconductor nanocrystal or the fourth semiconductor nanocrystal) may be greater than that of the first semiconductor nanocrystal. A layer including the third semiconductor nanocrystal or the fourth semiconductor nanocrystal may be the outermost layer of the semiconductor nanoparticle.

The semiconductor nanoparticle may have a core-shell structure with a core and a shell disposed on the core. The core may include the first semiconductor nanocrystal, and the shell may include the second semiconductor nanocrystal. The shell may be a multi-layered shell, and the multi-layered shell may include a first shell layer disposed on the core, a second shell layer disposed on the first shell layer, and a third shell layer disposed on the second shell layer. The first shell layer may include the third semiconductor nanocrystal. The second shell layer may include the second semiconductor nanocrystal. The third shell layer may include an additional semiconductor nanocrystal (e.g., the third semiconductor nanocrystal and/or the fourth semiconductor nanocrystal) including (a zinc chalcogenide or a zinc gallium chalcogenide including) zinc, sulfur, and optionally gallium.

In an embodiment, the semiconductor nanoparticle may include a core-multilayered shell structure such as AgInS/GaS, AgInS/GaSSe, AgInS/AgGaS, AgInS/AgGaSSe, AgInS/GaS/ZnGaS, AgInS/GaSSe/ZnGaS, AgInS/AgGaS/ZnGaS, AgInS/AgGaSSe/ZnGaS, AgInS/GaS/ZnS, AgInS/GaSSe/ZnS, AgInS/AgGaS/ZnS, AgInS/AgGaSSe/ZnS, AgInS/GaS/ZnGaS/ZnS, AgInS/GaSSe/ZnGaS/ZnS, AgInS/AgGaS/ZnGaS/ZnS, AgInS/AgGaS/ZnS, AgInGaS/AgGaS/ZnGaS/ZnS, or the like.

In the semiconductor nanoparticle, a concentration of indium may vary radially. In the semiconductor nanoparticle, the indium amount or concentration in an inner part of the semiconductor nanoparticle may differ from that in an outer part of the particle. In an embodiment, the indium amount or concentration in the portion adjacent to the surface (e.g., the outermost layer or shell) may be lower than the indium amount or concentration in the inner part of the particle (or core). In an embodiment, the zinc amount or concentration in the portion adjacent to the surface (e.g., in an outermost layer) may be higher than the zinc amount or concentration in an inner part of the particle (or core). In the semiconductor nanoparticle, the concentration of zinc may be higher in the outer part of the particle than in the inner part thereof. The core or the first semiconductor nanocrystal may not include zinc. In the shell, gallium may exhibit a radial concentration gradient (e.g., increasing or decreasing). In the shell, the concentration of gallium in the portion adjacent to the particle surface may be higher than the concentration of gallium in the portion adjacent to the core.

When incident light (e.g., blue light) is provided to a pixel and spreads out in a color conversion device such as a color conversion panel including a light-emitting material, the incident light absorbed by the semiconductor nanoparticle dispersed within the pixel can be converted into light of a desired color (e.g., red light). Optical density is a parameter related to absorbance and can be used as a method to quantify the concentration of solutes or semiconductor nanoparticles. According to Beer-Lambert's law, absorbance is proportional to the concentration of semiconductor nanoparticles and the absorption coefficient in a given sample solution. The optical density can be the optical attenuation per centimeter of the material, measured using a standard spectrometer, for example, with a 1 centimeter path length. The optical density of a nanoparticle-containing solution can be easily and reproducibly measured using a UV-Vis spectrometer (e.g., commercially available).

The optical density per weight in the semiconductor nanoparticle can represent the absorption property of the semiconductor nanoparticle. For example, to implement a color conversion pixel, a given weight of the semiconductor nanoparticles are added, and thus, an increased number (e.g., increased concentration) of semiconductor nanoparticles per weight is related to increased absorption of the semiconductor nanoparticle, which can lead to improved absorption in the pixel.

In the field of eco-friendly cadmium-free quantum dots, the development of semiconductor nanoparticles that can emit red light while exhibiting an increased absorption coefficient is desirable from the perspective of applications in electronic devices (e.g., display devices) with red pixels. If semiconductor nanoparticles have increased optical density per weight, the concentration of semiconductor nanoparticles in the color conversion pixel can be increased, which can also contribute to increased absorption in the pixel.

For high absorption efficiency, the core/shell structure of the semiconductor nanoparticle can be considered to increase the proportion of the core volume, which contributes to the actual absorption of blue light, within the total volume of the core/shell semiconductor nanoparticle, while minimizing the volume of the shell that does not contribute to absorption but plays an important role in physically separating excitons and surface defects to enhance quantum efficiency. In addition, a core with a composition having a high absorption coefficient may be desired for increasing the light absorption efficiency of the semiconductor nanoparticle.

The semiconductor nanoparticle of an embodiment, having the composition/structure described herein, can be included in a red pixel to achieve significantly increased absorption efficiency compared to conventional technology. The semiconductor nanoparticle of an embodiment can exhibit optical properties at a level suitable for use as a red light-emitting material within a pixel.

The semiconductor nanoparticle of an embodiment may include silver, indium, gallium, and sulfur, and in the semiconductor nanoparticle, the mole ratio of gallium to indium is greater than about 1:1, or greater than or equal to about 1.5:1 and less than or equal to about 20:1. The semiconductor nanoparticle is configured to emit a red light, and the red light may have a full width at half maximum (FWHM) of greater than or equal to about 5 nm and less than or equal to about 90 nm or greater than or equal to about 10 nm and less than or equal to about 50 nm.

The semiconductor nanoparticle may include a group 11-13-16 compound including silver, indium, and sulfur. The semiconductor nanoparticle may include a first semiconductor nanocrystal including (a group 11-13-16 compound including) silver, indium, and sulfur; and a second semiconductor nanocrystal including (a group 13-16 compound or a group 11-13-16 compound including) gallium and sulfur, and optionally silver. The semiconductor nanoparticle may further include or may not include zinc. In an embodiment, the semiconductor nanoparticle may further include a third semiconductor nanocrystal including zinc, sulfur, and optionally gallium, a fourth semiconductor nanocrystal including zinc and sulfur, or a combination thereof. The semiconductor nanoparticle may have a core-shell structure. The details of the first semiconductor nanocrystal, the second semiconductor nanocrystal, the third semiconductor nanocrystal, the fourth semiconductor nanocrystal, and the structure of the semiconductor nanoparticle are as described herein.

The first semiconductor nanocrystal may have a size or an average size (hereinafter, can be simply referred to as “size”) of greater than or equal to about 3 nm, greater than or equal to about 3.3 nm, greater than or equal to about 3.4 nm, greater than or equal to about 3.5 nm, greater than or equal to about 4 nm, or greater than or equal to about 5 nm and less than or equal to about 20 nm, less than or equal to about 18 nm, less than or equal to about 16 nm, less than or equal to about 15 nm, less than or equal to about 13 nm, less than or equal to about 12 nm, less than or equal to about 11 nm, less than or equal to about 10 nm, less than or equal to about 7 nm, or less than or equal to about 4 nm. In an embodiment, the size of the first semiconductor nanocrystal or the core may be in the range of about 3.5 nm to about 20 nm, about 4 nm to about 18 nm, about 4.2 nm to about 15 nm, about 4.5 nm to about 12 nm, about 5 nm to about 10 nm, about 7 nm to about 9 nm, or a combination thereof. Here, the size of the semiconductor nanoparticle or the semiconductor nanocrystal may be the (average) diameter or the (average) equivalent diameter. The size of the semiconductor nanoparticle or the semiconductor nanocrystal can be determined by appropriate means (e.g., electron microscopy analysis, ICP-AES and optical properties, or X-ray diffraction (XRD) analysis, etc.).

In this specification, unless otherwise stated, the ratio between elements are a mole ratio.

In the first semiconductor nanocrystal, a mole ratio of indium to silver (In:Ag) may be greater than or equal to about 2:1, greater than or equal to about 2.2:1, greater than or equal to about 2.4:1, or greater than or equal to about 2.8:1 and less than or equal to about 4:1, less than or equal to about 3.7:1, or less than or equal to about 2.6:1.

In the first semiconductor nanocrystal, a mole ratio of sulfur to silver (S:Ag) may be greater than or equal to about 3:1, greater than or equal to about 3.8:1, greater than or equal to about 4:1, or greater than or equal to about 4.5:1 and less than or equal to about 7:1, less than or equal to about 4.7:1, or less than or equal to about 4.5:1.

In the first semiconductor nanocrystal, a mole ratio of indium to sulfur (In:S) may be greater than or equal to about 0.5:1, greater than or equal to about 0.55:1, greater than or equal to about 0.58:1, greater than or equal to about 0.59:1, or greater than or equal to about 0.6:1 and less than or equal to about 1.5:1, less than or equal to about 1:1, less than or equal to about 0.9:1, less than or equal to about 0.8:1, less than or equal to about 0.7:1, or less than or equal to about 0.65:1.

In the first semiconductor nanocrystal, a mole ratio of a sum of indium and silver to sulfur ((In+Ag):S) may be greater than or equal to about 0.4:1, greater than or equal to about 0.6:1, greater than or equal to about 0.79:1, greater than or equal to about 0.8:1, greater than or equal to about 0.82:1, greater than or equal to about 0.83:1, greater than or equal to about 0.84:1, or greater than or equal to about 0.85:1 and less than or equal to about 1.5:1, less than or equal to about 1.3:1, less than or equal to about 1:1, less than or equal to about 0.95:1, less than or equal to about 0.91:1, or less than or equal to about 0.89:1.

In the first semiconductor nanocrystal, a mole ratio of a sum of indium and sulfur to silver ((In+S):Ag) may be greater than or equal to about 3.8:1, greater than or equal to about 4:1, greater than or equal to about 4.5:1, greater than or equal to about 5:1, greater than or equal to about 5.5:1, greater than or equal to about 6:1, greater than or equal to about 6.2:1, greater than or equal to about 6.4:1, greater than or equal to about 6.5:1, or greater than or equal to about 6.8:1 and less than or equal to about 8:1, less than or equal to about 7.4:1, less than or equal to about 7.2:1, less than or equal to about 7.1:1, or less than or equal to about 6.9:1.

The first semiconductor nanocrystal or the semiconductor nanoparticle may further include or may not include zinc. The first semiconductor nanocrystal may further include or may not include selenium.

The semiconductor nanoparticle or the first semiconductor nanocrystal may further include or may not include lithium. The semiconductor nanoparticle or the first semiconductor nanocrystal may further include or may not include an alkali metal (e.g., lithium, sodium, potassium, etc.).

In the semiconductor nanoparticle, a mole ratio of gallium to indium (Ga:In) may be greater than or equal to about 0.8:1, greater than or equal to about 0.85:1, greater than or equal to about 0.9:1, greater than or equal to about 0.95:1, greater than or equal to about 1:1, greater than or equal to about 1.1:1, greater than or equal to about 1.2:1, greater than or equal to about 1.3:1, greater than or equal to about 1.5:1, greater than or equal to about 1.7:1, greater than or equal to about 1.9:1, greater than or equal to about 2:1, greater than or equal to about 2.1:1, greater than or equal to about 2.3:1, greater than or equal to about 2.4:1, greater than or equal to about 2.5:1, greater than or equal to about 2.6:1, greater than or equal to about 2.65:1, greater than or equal to about 2.7:1, greater than or equal to about 2.8:1, greater than or equal to about 2.85:1, greater than or equal to about 2.9:1, or greater than or equal to about 3:1 and less than or equal to about 20:1, less than or equal to about 10:1, less than or equal to about 5:1, less than or equal to about 4.5:1, less than or equal to about 3.8:1, less than or equal to about 3.5:1, less than or equal to about 3.3:1, less than or equal to about 3.1:1, less than or equal to about 2.9:1, less than or equal to about 2.88:1, less than or equal to about 2.69:1, or less than or equal to about 2.47:1.

In the semiconductor nanoparticle, the mole ratio of gallium to a sum of indium and gallium (Ga:(In+Ga)) may be greater than or equal to about 0.5:1, greater than or equal to about 0.51:1, greater than or equal to about 0.52:1, greater than or equal to about 0.54:1, greater than or equal to about 0.545:1, greater than or equal to about 0.55:1, greater than or equal to about 0.56:1, greater than or equal to about 0.57:1, greater than or equal to about 0.59:1, greater than or equal to about 0.6:1, greater than or equal to about 0.63:1, greater than or equal to about 0.65:1, greater than or equal to about 0.68:1, greater than or equal to about 0.7:1, greater than or equal to about 0.71:1, greater than or equal to about 0.72:1, or greater than or equal to about 0.74:1 and less than or equal to about 0.99:1, less than or equal to about 0.9:1, less than or equal to about 0.85:1, less than or equal to about 0.8:1, less than or equal to about 0.75:1, less than or equal to about 0.745:1, less than or equal to about 0.741:1, less than or equal to about 0.728:1, or less than or equal to about 0.712:1.

In the semiconductor nanoparticle, a mole ratio of silver to indium (Ag:In) may be greater than or equal to about 0.5:1, greater than or equal to about 0.7:1, greater than or equal to about 0.8:1, greater than or equal to about 0.9:1, greater than or equal to about 0.94:1, greater than or equal to about 1:1, greater than or equal to about 1.2:1, greater than or equal to about 1.3:1, greater than or equal to about 1.4:1, greater than or equal to about 1.46:1, greater than or equal to about 1.48:1, greater than or equal to about 1.5:1, greater than or equal to about 1.55:1, greater than or equal to about 1.7:1, greater than or equal to about 1.75:1, or greater than or equal to about 1.8:1 and less than or equal to about 5:1, less than or equal to about 4:1, less than or equal to about 3:1, less than or equal to about 2.7:1, less than or equal to about 2.6:1, less than or equal to about 2.5:1, less than or equal to about 2.4:1, less than or equal to about 2.3:1, less than or equal to about 2.1:1, less than or equal to about 2:1, less than or equal to about 1.9:1, less than or equal to about 1.85:1, less than or equal to about 1.7:1, less than or equal to about 1.65:1, less than or equal to about 1.57:1, less than or equal to about 1.47:1, less than or equal to about 1.35:1, or less than or equal to about 1.25:1.

In the semiconductor nanoparticle, the mole ratio of gallium to silver (Ga:Ag) may be greater than or equal to about 0.8:1, greater than or equal to about 0.85:1, greater than or equal to about 0.9:1, greater than or equal to about 0.94:1, greater than or equal to about 0.99:1, greater than or equal to about 1:1, greater than or equal to about 1.1:1, greater than or equal to about 1.15:1, greater than or equal to about 1.2:1, greater than or equal to about 1.22:1, greater than or equal to about 1.29:1, greater than or equal to about 1.3:1, greater than or equal to about 1.33:1, greater than or equal to about 1.34:1, greater than or equal to about 1.36:1, greater than or equal to about 1.39:1, greater than or equal to about 1.4:1, greater than or equal to about 1.46:1, greater than or equal to about 1.48:1, greater than or equal to about 1.5:1, greater than or equal to about 1.54:1, greater than or equal to about 1.57:1, greater than or equal to about 1.6:1, or greater than or equal to about 1.65:1; less than or equal to about 3:1, less than or equal to about 2.9:1, less than or equal to about 2.8:1, less than or equal to about 2.75:1, less than or equal to about 2.6:1, less than or equal to about 2.5:1, less than or equal to about 2.2:1, less than or equal to about 2:1, less than or equal to about 1.9:1, less than or equal to about 1.8:1, less than or equal to about 1.75:1, less than or equal to about 1.7:1, less than or equal to about 1.65:1, less than or equal to about 1.6:1, less than or equal to about 1.58:1, less than or equal to about 1.55:1, less than or equal to about 1.5:1, less than or equal to about 1.45:1, less than or equal to about 1.4:1, or less than or equal to about 1.35:1; or a combination thereof.

In the semiconductor nanoparticle, the mole ratio of the sum of indium and gallium to silver ((In+Ga):Ag) may be greater than or equal to about 1.4:1, greater than or equal to about 1.41:1, greater than or equal to about 1.43:1, greater than or equal to about 1.45:1, greater than or equal to about 1.46:1, greater than or equal to about 1.48:1, greater than or equal to about 1.5:1, greater than or equal to about 1.56:1, greater than or equal to about 1.68:1, greater than or equal to about 1.7:1, greater than or equal to about 1.74:1, greater than or equal to about 1.81:1, greater than or equal to about 1.9:1, greater than or equal to about 1.94:1, greater than or equal to about 2.1:1, or greater than or equal to about 2.3:1; and less than or equal to about 3.5:1, less than or equal to about 3:1, less than or equal to about 2.2:1, less than or equal to about 2:1, less than or equal to about 1.96:1, less than or equal to about 1.95:1, or less than or equal to about 1.9:1; or a combination thereof.

In the semiconductor nanoparticle, the mole ratio of indium to sulfur (In:S) may be greater than or equal to about 0.18:1, greater than or equal to about 0.19:1, greater than or equal to about 0.22:1, greater than or equal to about 0.23:1, greater than or equal to about 0.25:1, greater than or equal to about 0.26:1, greater than or equal to about 0.27:1, greater than or equal to about 0.28:1, greater than or equal to about 0.29:1, greater than or equal to about 0.3:1, or greater than or equal to about 0.31:1; and less than or equal to about 0.5:1, less than or equal to about 0.35:1, less than or equal to about 0.3:1, less than or equal to about 0.295:1, less than or equal to about 0.29:1, less than or equal to about 0.28:1, less than or equal to about 0.275:1, less than or equal to about 0.25:1, less than or equal to about 0.24:1, less than or equal to about 0.21:1, less than or equal to about 0.2:1, or less than or equal to about 0.195:1.

In the semiconductor nanoparticle, the mole ratio of sulfur to indium (S:In) may be greater than or equal to about 3.2:1, greater than or equal to about 3.3:1, greater than or equal to about 3.4:1, greater than or equal to about 3.43:1, greater than or equal to about 3.5:1, greater than or equal to about 3.6:1, greater than or equal to about 3.7:1, greater than or equal to about 3.8:1, greater than or equal to about 3.82:1, greater than or equal to about 3.9:1, greater than or equal to about 4:1, greater than or equal to about 4.1:1, greater than or equal to about 4.2:1, greater than or equal to about 4.3:1, greater than or equal to about 4.4:1, greater than or equal to about 4.5:1, greater than or equal to about 4.6:1, greater than or equal to about 4.7:1, greater than or equal to about 4.8:1, greater than or equal to about 4.9:1, or greater than or equal to about 5:1, greater than or equal to about 5.2:1; or less than or equal to about 10.5:1, less than or equal to about 10:1, less than or equal to about 9.5:1, less than or equal to about 9:1, less than or equal to about 8.5:1, less than or equal to about 8:1, less than or equal to about 7.5:1, less than or equal to about 7:1, less than or equal to about 6.5:1, less than or equal to about 6:1, less than or equal to about 5.5:1, less than or equal to about 5.3:1, less than or equal to about 5.2:1, or less than or equal to about 4.55:1.

In the semiconductor nanoparticle, a mole ratio of gallium to sulfur (Ga:S) may be greater than or equal to about 0.25:1, greater than or equal to about 0.27:1, greater than or equal to about 0.29:1, greater than or equal to about 0.3:1, greater than or equal to about 0.31:1, greater than or equal to about 0.33:1, greater than or equal to about 0.34:1, greater than or equal to about 0.35:1, greater than or equal to about 0.36:1, greater than or equal to about 0.37:1, greater than or equal to about 0.38:1, greater than or equal to about 0.4:1, greater than or equal to about 0.45:1, greater than or equal to about 0.48:1, greater than or equal to about 0.49:1, greater than or equal to about 0.5:1, greater than or equal to about 0.51:1, greater than or equal to about 0.52:1, greater than or equal to about 0.53:1, greater than or equal to about 0.54:1, greater than or equal to about 0.55:1, greater than or equal to about 0.56:1, greater than or equal to about 0.57:1, greater than or equal to about 0.58:1, greater than or equal to about 0.59:1, greater than or equal to about 0.6:1, greater than or equal to about 0.63:1, greater than or equal to about 0.65:1, greater than or equal to about 0.67:1, greater than or equal to about 0.69:1, greater than or equal to about 0.7:1, or greater than or equal to about 0.72:1. In the semiconductor nanoparticle, the mole ratio of gallium to sulfur (Ga:S) may be less than or equal to about 1.2:1, less than or equal to about 1.1:1, less than or equal to about 1:1, less than or equal to about 0.95:1, less than or equal to about 0.9:1, less than or equal to about 0.85:1, less than or equal to about 0.8:1, less than or equal to about 0.79:1, less than or equal to about 0.75:1, less than or equal to about 0.77:1, less than or equal to about 0.73:1, less than or equal to about 0.71:1, less than or equal to about 0.7:1, less than or equal to about 0.69:1, less than or equal to about 0.68:1, less than or equal to about 0.65:1, less than or equal to about 0.64:1, less than or equal to about 0.61:1, less than or equal to about 0.6:1, less than or equal to about 0.56:1, less than or equal to about 0.54:1, less than or equal to about 0.52:1, or less than or equal to about 0.5:1.

In the semiconductor nanoparticle, a mole ratio of a sum of indium and gallium to sulfur [(In+Ga):S] may be greater than or equal to about 0.4:1, greater than or equal to about 0.45:1, greater than or equal to about 0.5:1, greater than or equal to about 0.52:1, greater than or equal to about 0.53:1, greater than or equal to about 0.54:1, greater than or equal to about 0.55:1, greater than or equal to about 0.57:1, greater than or equal to about 0.58:1, greater than or equal to about 0.59:1, greater than or equal to about 0.6:1, greater than or equal to about 0.61:1, greater than or equal to about 0.62:1, greater than or equal to about 0.63:1, greater than or equal to about 0.64:1, greater than or equal to about 0.65:1, greater than or equal to about 0.66:1, greater than or equal to about 0.68:1, greater than or equal to about 0.7:1, greater than or equal to about 0.72:1, greater than or equal to about 0.73:1, greater than or equal to about 0.74:1, greater than or equal to about 0.75:1, greater than or equal to about 0.77:1, greater than or equal to about 0.79:1, or greater than or equal to about 0.81:1 and less than or equal to about 1.5:1, less than or equal to about 1.3:1, less than or equal to about 1.1:1, less than or equal to about 1.05:1, less than or equal to about 1:1, less than or equal to about 0.9:1, less than or equal to about 0.88:1, less than or equal to about 0.86:1, less than or equal to about 0.84:1, less than or equal to about 0.82:1, less than or equal to about 0.78:1, less than or equal to about 0.73:1, less than or equal to about 0.71:1, less than or equal to about 0.69:1, or less than or equal to about 0.67:1.

In the semiconductor nanoparticle, a mole ratio of silver to sulfur (Ag:S) may be greater than or equal to about 0.2:1, greater than or equal to about 0.25:1, greater than or equal to about 0.27:1, greater than or equal to about 0.28:1, greater than or equal to about 0.3:1, greater than or equal to about 0.31:1, greater than or equal to about 0.32:1, greater than or equal to about 0.33:1, greater than or equal to about 0.34:1, greater than or equal to about 0.35:1, greater than or equal to about 0.36:1, greater than or equal to about 0.38:1, greater than or equal to about 0.39:1, greater than or equal to about 0.4:1, or greater than or equal to about 0.41:1, and less than or equal to about 0.65:1, less than or equal to about 0.6:1, less than or equal to about 0.5:1, less than or equal to about 0.45:1, less than or equal to about 0.44:1, less than or equal to about 0.43:1, less than or equal to about 0.42:1, less than or equal to about 0.41:1, less than or equal to about 0.4:1, less than or equal to about 0.39:1, less than or equal to about 0.37:1, less than or equal to about 0.36:1, or less than or equal to about 0.34:1.

In the semiconductor nanoparticle, a mole ratio of silver to a sum of silver, indium, and gallium [Ag:(Ag+In+Ga)] may be greater than or equal to about 0.15:1, greater than or equal to about 0.2:1, greater than or equal to about 0.25:1, greater than or equal to about 0.3:1, greater than or equal to about 0.31:1, greater than or equal to about 0.32:1, greater than or equal to about 0.33:1, greater than or equal to about 0.34:1, greater than or equal to about 0.35:1, greater than or equal to about 0.36:1, greater than or equal to about 0.37:1, greater than or equal to about 0.38:1, greater than or equal to about 0.39:1, greater than or equal to about 0.4:1, greater than or equal to about 0.41:1, greater than or equal to about 0.43:1, or greater than or equal to about 0.44:1, and less than or equal to about 0.45:1, less than or equal to about 0.42:1, less than or equal to about 0.40:1, less than or equal to about 0.36:1, less than or equal to about 0.33:1, less than or equal to about 0.32:1, or less than or equal to about 0.28:1.

In the semiconductor nanoparticle, a mole ratio of gallium to a sum of gallium, indium, and silver (Ga:(Ga+In+Ag)) may be greater than or equal to about 0.25:1, greater than or equal to about 0.3:1, greater than or equal to about 0.31:1, greater than or equal to about 0.33:1, greater than or equal to about 0.35:1, greater than or equal to about 0.4:1, greater than or equal to about 0.45:1, greater than or equal to about 0.46:1, greater than or equal to about 0.47:1, greater than or equal to about 0.48:1, greater than or equal to about 0.49:1, greater than or equal to about 0.5:1, greater than or equal to about 0.51:1, greater than or equal to about 0.52:1, greater than or equal to about 0.53:1, or greater than or equal to about 0.54:1; less than or equal to about 0.85:1, less than or equal to about 0.8:1, less than or equal to about 0.77:1, less than or equal to about 0.74:1, less than or equal to about 0.73:1, less than or equal to about 0.72:1, less than or equal to about 0.71:1, less than or equal to about 0.69:1, less than or equal to about 0.65:1, less than or equal to about 0.64:1, less than or equal to about 0.62:1, less than or equal to about 0.61:1, less than or equal to about 0.59:1, less than or equal to about 0.56:1, less than or equal to about 0.54:1, less than or equal to about 0.53:1, less than or equal to about 0.49:1, or less than or equal to about 0.485:1; or a combination thereof.

In the semiconductor nanoparticle, the mole ratio of sulfur to the sum of silver, indium, and gallium [S:(Ag+In+Ga)] may be greater than or equal to about 0.6:1, greater than or equal to about 0.7:1, greater than or equal to about 0.75:1, greater than or equal to about 0.8:1, greater than or equal to about 0.9:1, greater than or equal to about 0.91:1, greater than or equal to about 0.92:1, greater than or equal to about 1:1, greater than or equal to about 1.05:1, greater than or equal to about 1.12:1, or greater than or equal to about 1.3:1; and less than or equal to about 1.5:1, less than or equal to about 1.45:1, less than or equal to about 1.35:1, less than or equal to about 1.15:1, less than or equal to about 1.13:1, less than or equal to about 1.12:1, less than or equal to about 1.1:1, less than or equal to about 1.09:1, less than or equal to about 1.08:1, less than or equal to about 1.06:1, less than or equal to about 0.99:1, or less than or equal to about 0.95:1.

The semiconductor nanoparticle has a charge balance value defined by the following equation of greater than or equal to about 0.95, greater than or equal to about 0.98, greater than or equal to about 1, greater than or equal to about 1.05, or greater than or equal to about 1.1, and less than or equal to about 1.35, less than or equal to about 1.3, less than or equal to about 1.25, less than or equal to about 1.2, or less than or equal to about 1.1:

$$charge balance value = \{ [ Ag ] + 3 ( [ ln ] + [ Ga ] ) \} / 2 [ S ]$$

wherein [Ag], [In], [Ga], and [S] are moles of silver, indium, gallium, and sulfur, respectively, in the semiconductor nanoparticle.

The semiconductor nanoparticle, the first semiconductor nanocrystal, or the second semiconductor nanocrystal may further include selenium.

If present, a mole ratio of selenium to indium in the semiconductor nanoparticle may be greater than or equal to about 0.001, greater than or equal to about 0.003, greater than or equal to about 0.005, greater than or equal to about 0.007, greater than or equal to about 0.009, greater than or equal to about 0.01, greater than or equal to about 0.02, greater than or equal to about 0.025, greater than or equal to about 0.03, greater than or equal to about 0.035, greater than or equal to about 0.04, greater than or equal to about 0.045, greater than or equal to about 0.05, greater than or equal to about 0.055, greater than or equal to about 0.06, greater than or equal to about 0.07, greater than or equal to about 0.08, greater than or equal to about 0.09, greater than or equal to about 0.1, or greater than or equal to about 0.12. The mole ratio of selenium to indium in the semiconductor nanoparticle may be less than or equal to about 0.5, less than or equal to about 0.4, less than or equal to about 0.3, less than or equal to about 0.2, less than or equal to about 0.15, or less than or equal to about 0.12.

If present, a mole ratio of selenium to sulfur (Se:S) in the semiconductor nanoparticle may be greater than or equal to about 0.0001, greater than or equal to about 0.0003, greater than or equal to about 0.0005, greater than or equal to about 0.0007, greater than or equal to about 0.0009, greater than or equal to about 0.001, greater than or equal to about 0.002, greater than or equal to about 0.0025, greater than or equal to about 0.003, greater than or equal to about 0.0035, greater than or equal to about 0.004, greater than or equal to about 0.0045, greater than or equal to about 0.005, greater than or equal to about 0.0055, greater than or equal to about 0.006, greater than or equal to about 0.0065, greater than or equal to about 0.007, greater than or equal to about 0.0075, greater than or equal to about 0.008, greater than or equal to about 0.009, greater than or equal to about 0.01, greater than or equal to about 0.03, greater than or equal to about 0.05, greater than or equal to about 0.07, greater than or equal to about 0.08, greater than or equal to about 0.09, greater than or equal to about 0.1, or greater than or equal to about 0.12. The mole ratio of selenium to sulfur (Se:S) in the semiconductor nanoparticle may be less than or equal to about 0.5, less than or equal to about 0.4, less than or equal to about 0.3, less than or equal to about 0.2, less than or equal to about 0.15, less than or equal to about 0.13, less than or equal to about 0.11, or less than or equal to about 0.06.

If present, a mole ratio of selenium to silver (Se:Ag) in the semiconductor nanoparticle may be greater than or equal to about 0.001, greater than or equal to about 0.003, greater than or equal to about 0.005, greater than or equal to about 0.007, greater than or equal to about 0.008, greater than or equal to about 0.009, greater than or equal to about 0.01, greater than or equal to about 0.012, greater than or equal to about 0.02, greater than or equal to about 0.03, greater than or equal to about 0.04, greater than or equal to about 0.05, The mole ratio of selenium to silver (Se:Ag) in the semiconductor nanoparticle may be less than or equal to about 0.5, less than or equal to about 0.4, less than or equal to about 0.3, less than or equal to about 0.2, less than or equal to about 0.15, less than or equal to about 0.13, less than or equal to about 0.11, or less than or equal to about 0.06.

The size or average size (hereinafter referred to as size) of the first semiconductor nanocrystal may be greater than or equal to about 3 nm, greater than or equal to about 3.1 nm, greater than or equal to about 3.3 nm, greater than or equal to about 3.5 nm, greater than or equal to about 3.7 nm, greater than or equal to about 3.9 nm, greater than or equal to about 4 nm, greater than or equal to about 4.2 nm, greater than or equal to about 4.5 nm, greater than or equal to about 4.7 nm, greater than or equal to about 5 nm, greater than or equal to about 5.5 nm, or greater than or equal to about 6 nm. The size of the first semiconductor nanocrystal may be less than or equal to about 15 nm, less than or equal to about 13 nm, less than or equal to about 12 nm, less than or equal to about 11 nm, less than or equal to about 10 nm, less than or equal to about 8 nm, less than or equal to about 7 nm, less than or equal to about 6.5 nm, less than or equal to about 6.2 nm, less than or equal to about 5.5 nm, less than or equal to about 5 nm, less than or equal to about 4.5 nm, less than or equal to about 4 nm, or less than or equal to about 3.5 nm.

A thickness of the second semiconductor nanocrystal or a layer including the same may be greater than or equal to about 0.1 nm, greater than or equal to about 0.2 nm, greater than or equal to about 0.3 nm, greater than or equal to about 0.5 nm, greater than or equal to about 0.7 nm, greater than or equal to about 0.9 nm, greater than or equal to about 1 nm, greater than or equal to about 1.2 nm, greater than or equal to about 1.5 nm, greater than or equal to about 1.8 nm, greater than or equal to about 2 nm, greater than or equal to about 2.3 nm, greater than or equal to about 2.5 nm, greater than or equal to about 2.8 nm, greater than or equal to about 3 nm, greater than or equal to about 3.2 nm, greater than or equal to about 3.5 nm, greater than or equal to about 3.8 nm, or greater than or equal to about 4 nm. The thickness of the second semiconductor nanocrystal or a layer including the same may be less than or equal to about 10 nm, less than or equal to about 8 nm, less than or equal to about 6 nm, less than or equal to about 5 nm, less than or equal to about 4.5 nm, less than or equal to about 4.3 nm, less than or equal to about 4.1 nm, less than or equal to about 3.9 nm, less than or equal to about 3.3 nm, less than or equal to about 3 nm, less than or equal to about 2.5 nm, less than or equal to about 2 nm, less than or equal to about 1.5 nm, less than or equal to about 1 nm, or less than or equal to about 0.8 nm.

If present, a thickness of the third semiconductor nanocrystal, the fourth semiconductor nanocrystal, or a layer including the same may be greater than or equal to about 0.1 nm, greater than or equal to about 0.3 nm, greater than or equal to about 0.5 nm, greater than or equal to about 0.7 nm, or greater than or equal to about 1 nm. The thickness of the third semiconductor nanocrystal, the fourth semiconductor nanocrystal, or a layer including the same may be less than or equal to about 2 nm, less than or equal to about 1.5 nm, less than or equal to about 1 nm, or less than or equal to about 0.8 nm. The thickness of the third semiconductor nanocrystal, the fourth semiconductor nanocrystal, or a layer including the same may be in the range of about 0.1 nm to about 5 nm, about 0.2 nm to about 4 nm, about 0.3 nm to about 3.5 nm, about 0.4 nm to about 3 nm, about 0.5 nm to about 2.5 nm, about 0.6 nm to about 2 nm, about 0.7 nm to about 1.5 nm, about 0.8 nm to about 1.2 nm, about 0.9 nm to about 1 nm, or a combination thereof.

In an embodiment, the size (or average particle size, hereinafter simply referred to as “size”) of the semiconductor nanoparticle may be greater than or equal to about 3.5 nm, greater than or equal to about 4 nm, greater than or equal to about 4.5 nm, greater than or equal to about 5 nm, greater than or equal to about 5.5 nm, greater than or equal to about 6 nm, greater than or equal to about 6.5 nm, greater than or equal to about 7 nm, greater than or equal to about 7.5 nm, greater than or equal to about 8 nm, greater than or equal to about 8.5 nm, greater than or equal to about 9 nm, greater than or equal to about 9.5 nm, greater than or equal to about 10 nm, greater than or equal to about 10.5 nm, or greater than or equal to about 11 nm. The size of the semiconductor nanoparticle may be less than or equal to about 50 nm, less than or equal to about 48 nm, less than or equal to about 46 nm, less than or equal to about 44 nm, less than or equal to about 42 nm, less than or equal to about 40 nm, less than or equal to about 35 nm, less than or equal to about 30 nm, less than or equal to about 25 nm, less than or equal to about 20 nm, less than or equal to about 18 nm, less than or equal to about 16 nm, less than or equal to about 14 nm, less than or equal to about 12 nm, less than or equal to about 11 nm, less than or equal to about 10 nm, less than or equal to about 8 nm, less than or equal to about 7 nm, less than or equal to about 6 nm, or less than or equal to about 4 nm.

In this specification, the size of the semiconductor nanoparticle may be a particle diameter (e.g., an equivalent diameter). The size of the semiconductor nanoparticle can be obtained from images confirmed by electron microscopy (e.g., transmission electron microscopy). The size of the semiconductor nanoparticle may be an equivalent diameter obtained by a calculation involving converting the two-dimensional area of the particles obtained from electron microscope images into a circle. This particle size can be reproducibly and easily obtained from microscope images using various image processing programs (e.g., ImageJ or an in-house program that can be created using coding languages). The particle size may be a value (e.g., a nominal particle size) calculated from the composition of the semiconductor nanoparticles and the emission peak wavelength.

The semiconductor nanoparticle may have an average size of greater than or equal to about 5 nm, or greater than or equal to about 5.1 nm, greater than or equal to about 5.2 nm, and less than or equal to about 10 nm, less than or equal to about 7 nm, less than or equal to about 6.5 nm, less than or equal to about 6 nm, or less than or equal to about 5.4 nm. The semiconductor nanoparticle may have a size distribution, represented by the standard deviation, of less than or equal to about 30%, less than or equal to about 28%, less than or equal to about 26%, less than or equal to about 25%, less than or equal to about 24%, less than or equal to about 22%, less than or equal to about 21%, less than or equal to about 20%, less than or equal to about 19%, less than or equal to about 18%, less than or equal to about 17%, less than or equal to about 16%, less than or equal to about 15%, less than or equal to about 14%, less than or equal to about 13%, less than or equal to about 12%, less than or equal to about 11%, or less than or equal to about 10% of the average size. The standard deviation may be greater than or equal to about 5%, greater than or equal to about 10%, or greater than or equal to about 12%.

The semiconductor nanoparticle may be configured to emit red light. The emission peak wavelength of the red light may be greater than or equal to about 596 nm, greater than or equal to about 597 nm, greater than or equal to about 599 nm, greater than or equal to about 600 nm, greater than or equal to about 601 nm, greater than or equal to about 602 nm, greater than or equal to about 603 nm, greater than or equal to about 604 nm, greater than or equal to about 605 nm, greater than or equal to about 606 nm, greater than or equal to about 607 nm, greater than or equal to about 608 nm, greater than or equal to about 609 nm, greater than or equal to about 610 nm, greater than or equal to about 615 nm, greater than or equal to about 620 nm, or greater than or equal to about 625 nm and less than or equal to about 650 nm, less than or equal to about 645 nm, less than or equal to about 640 nm, less than or equal to about 638 nm, less than or equal to about 635 nm, less than or equal to about 633 nm, less than or equal to about 630 nm, less than or equal to about 628 nm, or less than or equal to about 624 nm.

The semiconductor nanoparticle may exhibit an increased level of quantum yield. The quantum yield may be an absolute quantum yield. The quantum yield may be greater than or equal to about 10%, greater than or equal to about 15%, greater than or equal to about 20%, greater than or equal to about 25%, greater than or equal to about 30%, greater than or equal to about 35%, greater than or equal to about 40%, greater than or equal to about 45%, greater than or equal to about 50%, greater than or equal to about 55%, greater than or equal to about 60%, greater than or equal to about 65%, greater than or equal to about 70%, greater than or equal to about 75%, greater than or equal to about 80%, greater than or equal to about 85%, greater than or equal to about 90%, or greater than or equal to about 95%. The quantum yield may be less than or equal to about 100%, less than or equal to about 99.5%, less than or equal to about 99%, less than or equal to about 98%, or less than or equal to about 97%.

The semiconductor nanoparticle or the red light may have a full width at half maximum (FWHM) of greater than or equal to about 5 nm, greater than or equal to about 10 nm, greater than or equal to about 15 nm, greater than or equal to about 20 nm, greater than or equal to about 25 nm, or greater than or equal to about 30 nm. The FWHM may be less than or equal to about 55 nm, less than or equal to about 50 nm, less than or equal to about 49 nm, less than or equal to about 48 nm, less than or equal to about 47 nm, less than or equal to about 46 nm, less than or equal to about 45 nm, less than or equal to about 40 nm, less than or equal to about 38 nm, less than or equal to about 36 nm, less than or equal to about 35 nm, less than or equal to about 34 nm, less than or equal to about 33 nm, less than or equal to about 32 nm, less than or equal to about 31 nm, less than or equal to about 30 nm, less than or equal to about 29 nm, less than or equal to about 28 nm, less than or equal to about 27 nm, less than or equal to about 26 nm, or less than or equal to about 25 nm.

The red light may be band-edge emission. In an embodiment, the semiconductor nanoparticle may predominantly exhibit band-edge emission. The relative band-edge emission intensity, defined by the following equation, in the photoluminescence spectrum of the semiconductor nanoparticle of an embodiment may be greater than or equal to about 1.5, greater than or equal to about 2, greater than or equal to about 3, greater than or equal to about 4, greater than or equal to about 5, or greater than or equal to about 10:

$$Relative band ‐ edge emission intensity = A 1 / A 2$$

A1: a spectrum intensity at the peak emission wavelength
A2: a maximum intensity in the tail emission range of the peak emission wavelength+50 nm or greater

The semiconductor nanoparticle of an embodiment may exhibit enhanced absorption efficiency.

In an embodiment, the semiconductor nanoparticle may have a weight-based optical density (unit: L*g⁻¹*cm⁻¹) (e.g., at 450 nm) of greater than or equal to about 0.8, greater than or equal to about 1, greater than or equal to about 1.2, greater than or equal to about 1.5, greater than or equal to about 1.8, greater than or equal to about 2, greater than or equal to about 2.1, greater than or equal to about 2.2, greater than or equal to about 2.3, or greater than or equal to about 2.4 in UV-Vis absorption spectroscopy. The semiconductor nanoparticle may have a weight-based optical density (unit L*g⁻¹*cm⁻¹) (e.g., at 450 nm) of less than or equal to about 4, less than or equal to about 3.5, less than or equal to about 3, or less than or equal to about 2.8 in UV-Vis absorption spectroscopy. The semiconductor nanoparticle may have a weight-based optical density (unit: L*g⁻¹*cm⁻¹) (e.g., at 450 nm) of greater than or equal to about 1.3, greater than or equal to about 1.4, greater than or equal to about 1.6, greater than or equal to about 1.9, or greater than or equal to about 2, and less than or equal to about 3.5 in UV-Vis absorption spectroscopy.

The semiconductor nanoparticle may have a ratio of absorption at 550 nm to absorption at 350 nm of greater than or equal to about 0.05:1, greater than or equal to about 0.08:1, greater than or equal to about 0.1:1, greater than or equal to about 0.12:1, greater than or equal to about 0.13:1, greater than or equal to about 0.14:1, greater than or equal to about 0.15:1, greater than or equal to about 0.18:1, greater than or equal to about 0.2:1, greater than or equal to about 0.23:1, greater than or equal to about 0.25:1, greater than or equal to about 0.3:1, greater than or equal to about 0.35:1, or greater than or equal to about 0.4:1 in UV-Vis absorption spectroscopy. The semiconductor nanoparticle may have a ratio of absorption at 550 nm to absorption at 350 nm of less than or equal to about 0.8:1, less than or equal to about 0.5:1, less than or equal to about 0.45:1, less than or equal to about 0.4:1, less than or equal to about 0.35:1, less than or equal to about 0.3:1, less than or equal to about 0.28:1, or less than or equal to about 0.2:1 in UV-Vis absorption spectroscopy.

The shape of the semiconductor nanoparticle is not particularly limited and may include, for example, spherical, polyhedral, pyramidal, multipod, cubic, nanotube, nanowire, nanofiber, nanosheet, or combinations thereof, but is not limited thereto.

The semiconductor nanoparticle may include an organic ligand and/or an organic solvent on a surface thereof. The organic ligand and/or organic solvent may be bound to the surface of the semiconductor nanoparticles in an embodiment. The organic ligands and organic solvents are as described herein.

The semiconductor nanoparticle can be manufactured according to the methods described herein. The semiconductor nanoparticle manufactured in an embodiment can exhibit the atomic mole ratios described herein and can emit red light with increased absorption efficiency and the desired full width at half maximum (FWHM). The manufactured semiconductor nanoparticle can be used as a wavelength conversion material in a color conversion layer, for example.

In an embodiment, a method of manufacturing the semiconductor nanoparticle may include preparing a first semiconductor nanocrystal including silver, indium, and sulfur; and contacting (e.g., reacting) a second sulfur precursor, the first semiconductor nanocrystal, and a gallium precursor in a second reaction medium including a second organic solvent (e.g., at a shell formation reaction temperature).

The details of the first semiconductor nanocrystal are as described herein.

In an embodiment, the preparation of the first semiconductor nanocrystal may include contacting (reacting) a silver precursor, a first sulfur precursor, and an indium precursor in a first reaction medium including a first organic solvent; and heating the first reaction medium to a core formation reaction temperature, wherein an amount of the first sulfur precursor is greater than or equal to about 2 moles, greater than or equal to about 2.1 moles, greater than or equal to about 2.2 moles, or greater than or equal to about 2.5 moles and less than or equal to about 20 moles per mole of the indium precursor. In the method, the first reaction medium may further include an organic ligand.

In the method of an embodiment, an amount of the first sulfur precursor may be greater than or equal to about 2 moles, greater than or equal to about 2.5 moles, greater than or equal to about 2.6 moles, greater than or equal to about 2.7 moles, greater than or equal to about 2.8 moles, greater than or equal to about 2.9 moles, greater than or equal to about 3 moles, greater than or equal to about 3.2 moles, greater than or equal to about 3.4 moles, greater than or equal to about 3.6 moles, greater than or equal to about 3.8 moles, greater than or equal to about 4 moles, greater than or equal to about 4.2 moles, greater than or equal to about 4.3 moles, or greater than or equal to about 4.4 moles, per mole of the indium precursor. In the method of an embodiment, the amount of the first sulfur precursor may be less than or equal to about 19 moles, less than or equal to about 16 moles, less than or equal to about 14 moles, less than or equal to about 12 moles, less than or equal to about 10 moles, less than or equal to about 8 moles, less than or equal to about 6 moles, less than or equal to about 5.5 moles, less than or equal to about 5.3 moles, less than or equal to about 5 moles, or less than or equal to about 4.5 moles per mole of the indium precursor. In the method, the amount of the first sulfur precursor may be greater than or equal to about 4 moles and less than or equal to about 8 moles per mole of the indium precursor.

In the method, an amount of the indium precursor may be greater than or equal to about 0.6 moles, greater than or equal to about 0.8 moles, greater than or equal to about 1 mole, greater than or equal to about 1.1 moles, greater than or equal to about 1.2 moles, greater than or equal to about 1.3 moles, greater than or equal to about 1.4 moles, or greater than or equal to about 1.5 moles per mole of the silver precursor. The amount of the indium precursor may be less than or equal to about 5 moles, less than or equal to about 4.5 moles, less than or equal to about 4 moles, less than or equal to about 3.5 moles, less than or equal to about 3 moles, less than or equal to about 2.5 moles, less than or equal to about 2 moles, less than or equal to about 1.9 moles, less than or equal to about 1.8 moles, less than or equal to about 1.7 moles, less than or equal to about 1.6 moles, less than or equal to about 1.55 moles, or less than or equal to about 1.5 moles per mole of the silver precursor.

An amount of the first sulfur precursor may be greater than or equal to about 2 moles, greater than or equal to about 2.5 moles, greater than or equal to about 3 moles, greater than or equal to about 3.6 moles, greater than or equal to about 4 moles, greater than or equal to about 4.5 moles, greater than or equal to about 5 moles, greater than or equal to about 5.6 moles, greater than or equal to about 6 moles, greater than or equal to about 6.3 moles, greater than or equal to about 6.5 moles, greater than or equal to about 6.6 moles, greater than or equal to about 6.7 moles, greater than or equal to about 7 moles, greater than or equal to about 7.1 moles, greater than or equal to about 7.14 moles, greater than or equal to about 7.2 moles, greater than or equal to about 7.3 moles, or greater than or equal to about 8 moles per mole of the silver precursor. The amount of the first sulfur precursor may be less than or equal to about 15 moles, less than or equal to about 14 moles, less than or equal to about 12 moles, less than or equal to about 10 moles, less than or equal to about 8.5 moles, less than or equal to about 7.5 moles, less than or equal to about 7 moles, or less than or equal to about 6.5 moles per mole of the silver precursor.

A core formation reaction temperature may be greater than or equal to about 100° C., greater than or equal to about 150° C., greater than or equal to about 180° C., greater than or equal to about 200° C., greater than or equal to about 210° C., greater than or equal to about 215° C., greater than or equal to about 220° C., greater than or equal to about 225° C., greater than or equal to about 230° C., or greater than or equal to about 240° C. The core formation reaction temperature may be less than or equal to about 300° C., less than or equal to about 280° C., less than or equal to about 260° C., less than or equal to about 240° C., less than or equal to about 230° C., less than or equal to about 220° C., less than or equal to about 210° C., or less than or equal to about 200° C.

A core formation reaction time can be appropriately selected considering the type of precursor and reaction temperature. In an embodiment, the core formation reaction time may be greater than or equal to about 1 minute, greater than or equal to about 5 minutes, greater than or equal to about 10 minutes, greater than or equal to about 15 minutes, greater than or equal to about 20 minutes, greater than or equal to about 25 minutes, greater than or equal to about 30 minutes, greater than or equal to about 40 minutes, greater than or equal to about 50 minutes, greater than or equal to about 1 hour, or greater than or equal to about 2 hours. In an embodiment, the core formation reaction time may be greater than or equal to about 10 minutes and less than or equal to about 4 hours, greater than or equal to about 30 minutes and less than or equal to about 3 hours, or a combination thereof.

The preparation of the first semiconductor nanocrystal may include dissolving the silver precursor and the indium precursor in the first organic solvent to prepare a first reaction medium; vacuum treating the first reaction medium at a predetermined temperature (e.g., about 20° C. to about 100° C., about 30° C. to about 60° C., or room temperature); and adding the first sulfur precursor and optionally an organic ligand to the vacuum-treated first reaction medium.

The preparation of the first semiconductor nanocrystal may include maintaining the first reaction medium including the silver precursor, the indium precursor, the first sulfur precursor, and optionally a selenium precursor at a temperature of greater than or equal to about 30° C. and less than or equal to about 100° C., or greater than or equal to about 35° C. and less than or equal to about 60° C. for a predetermined time (e.g., greater than or equal to about 1 minute and less than or equal to about 100 minutes, greater than or equal to about 3 minutes and less than or equal to about 90 minutes, greater than or equal to about 5 minutes and less than or equal to about 75 minutes, or greater than or equal to about 10 minutes and less than or equal to about 50 minutes).

The first reaction medium may further include or may not include a gallium precursor, a copper precursor, a zinc precursor, a selenium precursor, or a combination thereof. In the core formation of an embodiment, an additional organic ligand may be added to the reaction solution. The manufactured first semiconductor nanocrystal can be separated and optionally washed. The addition, separation, and washing of the organic ligand can be performed by the methods described herein.

In an embodiment, the method may include contacting (e.g., reacting) a second sulfur precursor, the first semiconductor nanocrystal, and a gallium precursor in a second reaction medium including a second organic solvent (e.g., at a shell formation reaction temperature). The second reaction medium can be heated to a predetermined temperature or the shell formation reaction temperature. The second semiconductor nanocrystal can be formed on the first semiconductor nanocrystal by the contact or the reaction.

In an embodiment, the gallium precursor may include a gallium halide (e.g., a gallium chloride, a gallium bromide, a gallium iodide, a gallium fluoride, etc.). The predetermined temperature or the shell formation reaction temperature may be greater than or equal to about 120° C. and less than or equal to about 380° C. The predetermined temperature or the shell formation reaction temperature may be greater than or equal to about 220° C. and less than or equal to about 280° C.

In an embodiment, the method may include adding the second sulfur precursor to the second reaction medium (e.g., including an organic solvent and optionally an organic ligand). The second reaction medium can be vacuum-treated as described herein. In an embodiment, the method may include adding the gallium precursor to the second reaction medium. In an embodiment, the method may include adding the first semiconductor nanocrystal to the second reaction medium. The method of an embodiment may further include or may not include adding a selenium precursor to the first reaction medium or the second reaction medium (e.g., including an organic solvent and optionally an organic ligand). The second reaction medium may further include or may not include an indium precursor.

The method may include heating the second reaction medium (e.g., including the second sulfur precursor, the gallium precursor, the first semiconductor nanocrystal, or a combination thereof) to a predetermined temperature (e.g., reaction temperature or lower). The method may further include adding a non-solvent or a non-solvent mixture to the final reaction solution (e.g., after heating) to promote the precipitation of the semiconductor nanoparticles (e.g., coordinated with the organic ligand).

The method may further include adding a silver compound to the reaction medium.

A manner of adding the silver compound to the (reaction) medium (e.g., addition order or addition form) is not particularly limited. The silver compound can be added in a state dissolved in an appropriate organic solvent (e.g., an organic solvent described herein, such as an amine solvent like oleylamine, or a phosphine solvent like trioctylphosphine). The timing of adding the silver compound is not particularly limited and can be appropriately selected. The silver compound can be added to the (reaction) medium before or after the addition of the first semiconductor nanocrystal, the gallium precursor, the sulfur precursor, or a combination thereof. In an embodiment, the silver compound can be added to the (reaction) medium after the pretreatment.

The silver compound can be added to the medium in an amount of greater than or equal to about 0.01 mol %, greater than or equal to about 0.03 mol %, greater than or equal to about 0.04 mol %, greater than or equal to about 0.05 mol %, greater than or equal to about 0.052 mol %, greater than or equal to about 0.07 mol %, greater than or equal to about 0.09 mol %, greater than or equal to about 0.1 mol %, greater than or equal to about 0.2 mol %, for example, greater than or equal to about 0.5 mol % and less than or equal to about 50 mol %, for example, less than or equal to about 25 mol % relative to the gallium precursor.

The amount of the silver compound may be greater than or equal to about 0.01 mol %, greater than or equal to about 0.02 mol %, greater than or equal to about 0.03 mol %, greater than or equal to about 0.04 mol %, greater than or equal to about 0.045 mol %, greater than or equal to about 0.05 mol %, greater than or equal to about 0.052 mol %, greater than or equal to about 0.06 mol %, greater than or equal to about 0.07 mol %, greater than or equal to about 0.09 mol %, greater than or equal to about 0.1 mol %, greater than or equal to about 0.3 mol %, greater than or equal to about 0.5 mol %, greater than or equal to about 0.6 mol %, greater than or equal to about 0.7 mol %, greater than or equal to about 0.8 mol %, greater than or equal to about 0.9 mol %, greater than or equal to about 1 mol %, greater than or equal to about 2 mol %, greater than or equal to about 3 mol %, greater than or equal to about 4 mol %, greater than or equal to about 5 mol %, greater than or equal to about 6 mol %, greater than or equal to about 7 mol %, greater than or equal to about 8 mol %, greater than or equal to about 9 mol %, greater than or equal to about 10 mol %, greater than or equal to about 11 mol %, greater than or equal to about 12 mol %, greater than or equal to about 13 mol %, greater than or equal to about 14 mol %, or greater than or equal to about 15 mol % relative to the gallium precursor. The amount of the silver compound may be less than or equal to about 50 mol %, less than or equal to about 30 mol %, less than or equal to about 25 mol %, less than or equal to about 20 mol %, less than or equal to about 18 mol %, less than or equal to about 17 mol %, less than or equal to about 16 mol %, less than or equal to about 15 mol %, less than or equal to about 14 mol %, less than or equal to about 13 mol %, less than or equal to about 12 mol %, less than or equal to about 11 mol %, less than or equal to about 10 mol %, less than or equal to about 9 mol %, less than or equal to about 8 mol %, less than or equal to about 7 mol %, less than or equal to about 6 mol %, less than or equal to about 5 mol %, less than or equal to about 4 mol %, or less than or equal to about 3 mol % relative to the gallium precursor. The amount of the silver compound may be greater than or equal to about 1 mol % and less than or equal to about 12 mol % relative to the gallium precursor.

The silver compound may include a silver carboxylate, a silver acetylacetonate, a silver halide, or a combination thereof.

In an embodiment, the formation of the semiconductor nanoparticle may include performing a reaction between the gallium precursor and the second sulfur precursor in the presence of the first semiconductor nanocrystal including a Group 13 element and a chalcogen element. The second reaction medium may be a reaction medium for the shell formation reaction.

The details of the semiconductor nanoparticle and the first semiconductor nanocrystal are as described herein.

The method may include pretreating the second reaction medium.

In an embodiment, the method may include adding the first semiconductor nanocrystal and the gallium precursor, the second sulfur precursor, or both to the second reaction medium including an organic solvent (and optionally the second sulfur precursor). The second reaction medium (e.g., including the second sulfur precursor) can be pretreated at a predetermined temperature under vacuum before adding the first semiconductor nanocrystal or the gallium precursor. The pretreatment temperature can be lower than the reaction temperature. The pretreatment temperature may be, for example, greater than or equal to about 80° C., greater than or equal to about 100° C., or greater than or equal to about 120° C. and less than or equal to about 200° C., or less than or equal to about 180° C.

A manner of adding the first semiconductor nanocrystal, the gallium precursor, and the sulfur precursor (e.g., addition order or addition form) is not particularly limited. The first semiconductor nanocrystal can be dispersed in an appropriate organic solvent and added to the second reaction medium, but it is not limited thereto. The gallium precursor can be dispersed in an appropriate organic solvent (e.g., toluene) and added to the second reaction medium, but it is not limited thereto.

In an embodiment, the predetermined temperature may be greater than or equal to about 120° C., greater than or equal to about 180° C., greater than or equal to about 190° C., greater than or equal to about 200° C., greater than or equal to about 205° C., greater than or equal to about 210° C., greater than or equal to about 240° C., greater than or equal to about 245° C., greater than or equal to about 250° C., greater than or equal to about 255° C., greater than or equal to about 260° C., greater than or equal to about 265° C., greater than or equal to about 270° C., greater than or equal to about 275° C., greater than or equal to about 280° C., greater than or equal to about 285° C., greater than or equal to about 290° C., greater than or equal to about 295° C., greater than or equal to about 300° C., greater than or equal to about 305° C., greater than or equal to about 310° C., greater than or equal to about 315° C., greater than or equal to about 320° C., greater than or equal to about 330° C., greater than or equal to about 335° C., greater than or equal to about 340° C., or greater than or equal to about 345° C. The predetermined temperature may be less than or equal to about 380° C., less than or equal to about 375° C., less than or equal to about 370° C., less than or equal to about 365° C., less than or equal to about 360° C., less than or equal to about 355° C., less than or equal to about 350° C., less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., less than or equal to about 260° C., or less than or equal to about 250° C.

In an embodiment, the method may include heating the second reaction medium (optionally including the sulfur precursor) to a first temperature under vacuum or an inert atmosphere, and adding the first semiconductor nanocrystal, the gallium precursor, the sulfur precursor, or a combination thereof to the second reaction medium heated to the first temperature. In an embodiment, the method may include heating the reaction mixture including the first semiconductor nanocrystal, the gallium precursor, and the sulfur precursor to a second temperature (e.g., reaction temperature).

The first temperature may be greater than or equal to about 120° C. (e.g., greater than or equal to about 180° C., greater than or equal to about 190° C., or greater than or equal to about 200° C.) and less than or equal to about 280° C. (e.g., less than or equal to about 250° C.). The second temperature is greater than or equal to about 190° C., or greater than or equal to about 240° C. and less than or equal to about 380° C., or less than or equal to about 280° C. The second temperature may be higher than the first temperature. A difference between the first temperature and the second temperature may be greater than or equal to about 5° C., greater than or equal to about 10° C., greater than or equal to about 15° C., greater than or equal to about 20° C., greater than or equal to about 30° C., greater than or equal to about 40° C., greater than or equal to about 50° C., greater than or equal to about 60° C., greater than or equal to about 70° C., greater than or equal to about 80° C., greater than or equal to about 90° C., or greater than or equal to about 100° C. The difference between the first temperature and the second temperature may be less than or equal to about 200° C., less than or equal to about 190° C., less than or equal to about 180° C., less than or equal to about 170° C., less than or equal to about 160° C., less than or equal to about 150° C., less than or equal to about 140° C., less than or equal to about 130° C., less than or equal to about 120° C., less than or equal to about 110° C., less than or equal to about 100° C., less than or equal to about 90° C., less than or equal to about 80° C., less than or equal to about 70° C., less than or equal to about 60° C., less than or equal to about 50° C., less than or equal to about 40° C., less than or equal to about 30° C., or less than or equal to about 20° C.

The first temperature may be greater than or equal to about 120° C., greater than or equal to about 190° C., greater than or equal to about 200° C., greater than or equal to about 210° C., greater than or equal to about 220° C., greater than or equal to about 230° C., greater than or equal to about 240° C., or greater than or equal to about 250° C. The first temperature may be less than or equal to about 280° C., less than or equal to about 275° C., less than or equal to about 270° C., less than or equal to about 265° C., less than or equal to about 260° C., less than or equal to about 255° C., less than or equal to about 250° C., less than or equal to about 240° C., less than or equal to about 230° C., less than or equal to about 220° C., less than or equal to about 210° C., less than or equal to about 200° C., less than or equal to about 190° C., less than or equal to about 180° C., less than or equal to about 170° C., less than or equal to about 160° C., or less than or equal to about 150° C.

The second temperature (e.g., reaction temperature) may be greater than or equal to about 210° C., greater than or equal to about 220° C., greater than or equal to about 230° C., greater than or equal to about 240° C., greater than or equal to about 245° C., greater than or equal to about 250° C., greater than or equal to about 255° C., greater than or equal to about 260° C., greater than or equal to about 265° C., greater than or equal to about 270° C., greater than or equal to about 275° C., greater than or equal to about 280° C., greater than or equal to about 285° C., greater than or equal to about 290° C., greater than or equal to about 295° C., greater than or equal to about 300° C., greater than or equal to about 305° C., greater than or equal to about 310° C., greater than or equal to about 315° C., greater than or equal to about 320° C., greater than or equal to about 330° C., greater than or equal to about 335° C., greater than or equal to about 340° C., or greater than or equal to about 345° C. The second temperature may be less than or equal to about 380° C., less than or equal to about 375° C., less than or equal to about 370° C., less than or equal to about 365° C., less than or equal to about 360° C., less than or equal to about 355° C., less than or equal to about 350° C., less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., less than or equal to about 260° C., or less than or equal to about 250° C.

The reaction time may be appropriately controlled in consideration of the precursor and reaction temperature. The reaction time may be greater than or equal to about 30 minutes, greater than or equal to about 35 minutes, greater than or equal to about 40 minutes, greater than or equal to about 45 minutes, greater than or equal to about 50 minutes, greater than or equal to about 55 minutes, greater than or equal to about 60 minutes, greater than or equal to about 65 minutes, greater than or equal to about 70 minutes, greater than or equal to about 75 minutes, or greater than or equal to about 80 minutes.

In an embodiment, the method may further include preparing an additional reaction medium containing an organic solvent and an organic ligand; heating the additional reaction medium; and in the additional reaction medium, contacting (reacting) a zinc precursor, a gallium precursor, and a sulfur precursor, for example, at a reaction temperature, in the presence of the first semiconductor nanocrystal containing indium, gallium, silver, and sulfur or a particle including the same (e.g., the formed semiconductor nanoparticle) to further form a third semiconductor nanocrystal on the formed semiconductor nanoparticle. The third semiconductor nanocrystal may include a zinc gallium sulfide (ZnGaS). Details about the third semiconductor nanocrystal are the same as described herein.

The method may further include preparing an additional reaction medium containing an organic ligand in an organic solvent; heating the additional reaction medium; and in the presence of the formed semiconductor nanoparticle, contacting (e.g., reacting) a zinc precursor and a chalcogen precursor (e.g., a sulfur precursor), for example, at a reaction temperature, to provide a fourth semiconductor nanocrystal or an outer layer containing a zinc chalcogenide on a surface of the semiconductor nanoparticle. Details about the fourth semiconductor nanocrystal are the same as described herein.

In an embodiment, the reaction temperature for forming the third semiconductor nanocrystal or the fourth semiconductor nanocrystal may be greater than or equal to about 120° C., greater than or equal to about 130° C., greater than or equal to about 150° C., greater than or equal to about 180° C., greater than or equal to about 200° C., greater than or equal to about 205° C., or greater than or equal to about 208° C., and less than or equal to about 240° C., less than or equal to about 230° C., less than or equal to about 225° C., or less than or equal to about 215° C. The reaction time for forming the third semiconductor nanocrystal or the fourth semiconductor nanocrystal may be greater than or equal to about 10 minutes, greater than or equal to about 30 minutes, greater than or equal to about 40 minutes, greater than or equal to about 1 hour, greater than or equal to about 80 minutes, or greater than or equal to about 90 minutes, and less than or equal to about 5 hours, less than or equal to about 4 hours, less than or equal to about 3 hours, less than or equal to about 2 hours, less than or equal to about 90 minutes, or less than or equal to about 70 minutes.

In the method, the manner of adding the precursor to the (e.g., heated) reaction medium may include a shot addition (e.g., a syringe addition), a dropwise addition, or a combination thereof.

A type of a silver precursor is not particularly limited, and may be selected appropriately. The silver precursor may include a silver powder, an alkylated silver compound, a silver alkoxide, a silver carboxylate, a silver acetylacetonate, a silver nitrate, a silver sulfate, a silver halide, a silver cyanide, a silver hydroxide, a silver oxide, a silver peroxide, a silver carbonate, or a combination thereof. The silver precursor may include a silver nitrate, a silver acetate, a silver acetylacetonate, or a combination thereof.

A type of an indium precursor is not particularly limited and may be selected appropriately. The indium precursor may include an indium powder, an alkylated indium compound, an indium alkoxide, an indium carboxylate, an indium nitrate, an indium perchlorate, an indium sulfate, an indium acetylacetonate, an indium halide, an indium cyanide, an indium hydroxide, an indium oxide, an indium peroxide, an indium carbonate, or a combination thereof. The indium precursor may include an indium carboxylate (such as indium oleate, indium myristate, and an indium acetate), an indium hydroxide, indium chloride, indium bromide, indium iodide, or a combination thereof.

A type of sulfur precursor is not particularly limited and may be appropriately selected, The sulfur precursor may be an organic solvent dispersion or a reaction product of sulfur and an organic solvent (for example, a octadecene sulfide (S-ODE), a trioctylphosphine-sulfide (S-TOP), a tributylphosphine-sulfide (S-TBP), a triphenylphosphine-sulfide (S-TPP), a trioctylamine-sulfide (S-TOA)), a trimethylsilylalkyl sulfide, a trimethylsilyl sulfide, a mercapto propyl silane, an ammonium sulfide, a sodium sulfide, a C1-30 thiol compound (e.g., α-toluene thiol, octane thiol, dodecanethiol, octadecene thiol, or the like), an isothiocyanate compound (e.g., cyclohexylisothiocyanate, or the like), alkylenetrithiocarbonate (e.g., ethylene trithiocarbonate or the like), allyl mercaptan, a thiourea compound (e.g., dialkylthiourea having a C1 to C40 alkyl group such as dimethylthiourea, diethyl thiourea, ethyl methyl thiourea, dipropyl thiourea, or the like), a thioacetamide compound, or a combination thereof.

The selenium precursor, if present, may include selenium-trioctylphosphine (Se-TOP), selenium-tributylphosphine (Se-TBP), selenium-triphenylphosphine (Se-TPP), or a combination thereof.

A type of zinc precursor is not particularly limited and may be appropriately selected. In an embodiment, the zinc precursor may include a Zn metal powder, an alkylated Zn compound, a Zn alkoxide, a Zn carboxylate, a Zn nitrate, a Zn perchlorate, a Zn sulfate, a Zn acetylacetonate, a Zn halide, a Zn cyanide, a Zn hydroxide, a Zn oxide, a Zn peroxide, or a combination thereof. The zinc precursor may be dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, or a combination thereof. In an embodiment, when the semiconductor nanocrystal layer containing zinc and sulfur is formed, the zinc precursor may include Zn halide, but is not limited thereto.

A type of a gallium precursor for example used for the preparation of the first semiconductor nanocrystal or the additional semiconductor nanocrystal is not particularly limited and may be appropriately selected. The gallium precursor may include a gallium powder, an alkylated gallium compound, a gallium alkoxide, a gallium carboxylate, a gallium nitrate, a gallium perchlorate, a gallium sulfate, a gallium acetylacetonate, a gallium halide, a gallium cyanide, a gallium hydroxide, a gallium oxide, a gallium peroxide, a gallium carbonate, or a combination thereof. The gallium precursor may include gallium chloride, gallium iodide, gallium bromide, a gallium acetate, a gallium acetylacetonate, gallium oleate, gallium palmitate, gallium stearate, gallium myristate, a gallium hydroxide, or a combination thereof.

The organic ligand may include RCOOH, RNH₂, R₂NH, R₃N, RSH, RH₂PO, R₂HPO, R₃PO, RH₂P, R₂HP, R₃P, ROH, RCOOR′, RPO (OH)₂, RHPOOH, R₂POOH (wherein, R and R′ are each independently substituted or unsubstituted C1 to C40 (or C3 to C24) aliphatic hydrocarbon group (e.g., an alkyl group, an alkenyl group, or an alkynyl group), or a substituted or unsubstituted C6 to C40 (or C6 to C24) aromatic hydrocarbon group (e.g., a C6 to C20 aryl group)), or a combination thereof. The organic ligand may be bound to the surface of the semiconductor nanoparticle. Examples of the organic ligand may include methane thiol, ethane thiol, propane thiol, butane thiol, pentane thiol, hexane thiol, heptane thiol, octane thiol, 1-nonanethiol, decanethiol, dodecane thiol, hexadecane thiol, octadecane thiol, benzyl thiol; methyl amine, ethyl amine, propyl amine, butyl amine, pentyl amine, hexyl amine, octyl amine, dodecyl amine, hexadecyl amine, octadecyl amine, dimethyl amine, diethyl amine, dipropyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; substituted or unsubstituted methyl phosphine (e.g., trimethyl phosphine, methyldiphenyl phosphine, or the like), substituted or unsubstituted ethyl phosphine (e.g., triethyl phosphine, ethyldiphenyl phosphine, or the like), substituted or unsubstituted propyl phosphine, substituted or unsubstituted butyl phosphine, substituted or unsubstituted pentyl phosphine, substituted or unsubstituted octylphosphine (e.g., trioctylphosphine (TOP) or the like); a phosphine oxide such as substituted or unsubstituted methyl phosphine oxide (e.g., trimethyl phosphine oxide, methyldiphenyl phosphine oxide, or the like), substituted or unsubstituted ethyl phosphine oxide (e.g., triethyl phosphine oxide, ethyldiphenyl phosphine oxide, or the like), substituted or unsubstituted propyl phosphine oxide, substituted or unsubstituted butyl phosphine oxide, substituted or unsubstituted octylphosphine oxide (e.g., trioctylphosphine oxide (TOPO), or the like); diphenyl phosphine, a triphenyl phosphine compound, or an oxide compound thereof; phosphonic acid; a C5 to C20 alkyl phosphonic acid; a C5 to C20 alkylphosphinic acid such as hexylphosphinic acid, octylphosphinic acid, dodecanephosphinic acid, tetradecanephosphinic acid, hexadecanephosphinic acid, octadecanephosphinic acid, or the like, but embodiments are not limited thereto, The organic ligand may be used alone or as a mixture of two or more.

The organic solvent may include an amine solvent (e.g., a C1-50 aliphatic amine); a nitrogen-containing heterocyclic compound such as pyridine; a C6 to C40 aliphatic hydrocarbon (e.g., alkane, alkene, alkyne, or the like) such as hexadecane, octadecane, octadecene, squalene, or the like; a C6 to C30 aromatic hydrocarbon such as phenyldodecane, phenyltetradecane, phenyl hexadecane, or the like; a phosphine substituted with a C6 to C22 alkyl group such as trioctylphosphine or the like; a phosphine oxide substituted with a C6 to C22 alkyl group such as trioctylphosphine oxide, or the like; a C12 to C22 aromatic ether such as a phenyl ether, a benzyl ether, or the like; or a combination thereof, The amine solvent may be a compound having one or more (e.g., two or three) C1-50, C2-45, C3-40, C4-35, C5-30, C6-25, C7-20, C8-15, or C6-22 aliphatic hydrocarbon groups (e.g., alkyl group, alkenyl group, or alkynyl group). In an embodiment, the amine solvent may be a C6-22 primary amine such as hexadecyl amine, oleylamine, or the like; a C6-22 secondary amine such as dioctyl amine or the like; a C6-22 tertiary amine such as trioctylamine or the like; or a combination thereof.

Amounts of the organic ligand and each precursor in the reaction medium can be appropriately selected in consideration of the type of solvent, the type of organic ligand and each precursor, the desired particle size and composition, etc. Molar ratios among the precursors can be appropriately selected in consideration of the desired molar ratio in the final nanoparticles, the reactivity between the precursors, etc. The manner of adding each precursor is not particularly limited. The addition of each precursor can be performed simultaneously or sequentially. The reaction can be performed in an inert gas atmosphere, in air, or in a vacuum, but is not limited thereto.

After the reaction, an organic ligand (e.g., an alkylphosphine compound such as trioctylphosphine) can be added to the reaction solution. When a nonsolvent is added to the final reaction solution after the reaction (e.g., the nanoparticles coordinated with the organic ligand), the nanoparticles can be separated (e.g., precipitated). The nonsolvent can be a polar solvent that mixes with the solvent used in the reaction but cannot disperse the nanocrystals. The nonsolvent can be determined according to the solvent used in the reaction and may include, for example, acetone, ethanol, butanol, isopropanol, ethylene glycol, water, tetrahydrofuran (THF), dimethyl sulfoxide (DMSO), diethyl ether, formaldehyde, acetaldehyde, solvents having similar solubility parameters to the above-mentioned solvents, or combinations thereof. Separation can be performed using centrifugation, precipitation, chromatography, or distillation. The separated nanocrystals can be washed with a washing solvent as needed. The washing solvent is not particularly limited and can be a solvent having a solubility parameter similar to that of the organic solvent or ligand. Examples of the non-solvent or the washing solvent may include an alcohol; an alkane solvent such as hexane, heptane, octane; chloroform; an aromatic solvent such as toluene, benzene; or combinations thereof, but are not limited thereto. The nonsolvent can be a mixture of an aliphatic hydrocarbon solvent such as hexane and an alcohol solvent such as ethanol.

The manufactured semiconductor nanoparticles can be dispersed in a dispersion solvent. The manufactured semiconductor nanoparticles can form an organic solvent dispersion. The organic solvent dispersion may or may not include water and/or a water-miscible organic solvent. The dispersion solvent can be appropriately selected. The dispersion solvent may include the aforementioned organic solvents. The dispersion solvent may include a substituted or unsubstituted C1 to C40 aliphatic hydrocarbon, a substituted or unsubstituted C6 to C40 aromatic hydrocarbon, or combinations thereof.

In an embodiment, a composite may include a matrix; and the semiconductor nanoparticle described herein, wherein the semiconductor nanoparticle may be dispersed in the matrix. The composite may further contain a metal oxide fine particle. The composite or the semiconductor nanoparticle may be configured to emit red light. In an embodiment, the composite may be in the form of a patterned film. The composite may further include a semiconductor nanoparticle configured to emit second light different from the red light. In an embodiment, the composite may have a sheet form. The sheet may further include a semiconductor nanoparticle (e.g., an additional semiconductor nanoparticle) configured to emit second light (e.g., a green light) different from the red light.

The semiconductor nanoparticle described herein or the composite including the semiconductor nanoparticle may exhibit an increased level of blue light absorbance (e.g., an improved incident light absorbance) and/or improved optical properties (e.g., an increased luminescent efficiency and a narrower full width at half maximum), and may emit light of a desired wavelength (e.g., first light or red light).

The composite may include the semiconductor nanoparticle or a population thereof (e.g., in a predetermined amount) and exhibit increased light absorbance. An incident light absorbance of the composite may be greater than or equal to about 70%, greater than or equal to about 73%, greater than or equal to about 75%, greater than or equal to about 77%, greater than or equal to about 80%, greater than or equal to about 83%, greater than or equal to about 85%, greater than or equal to about 87%, greater than or equal to about 90%, greater than or equal to about 93%, greater than or equal to about 94%, greater than or equal to about 95%, greater than or equal to about 96%, greater than or equal to about 97%, greater than or equal to about 98%, or greater than or equal to about 99%. The blue light absorbance of the composite may be about 70% to about 100%, about 80% to about 98%, about 95% to about 99%, about 96% to about 98%, or a combination thereof.

The incident light absorbance of the composite may be calculated according to Equation 1:

$$incident light absorbance = [ ( B - {B}^{′} ) / B ] \times 100 \% \qquad Equation 1$$

wherein, in Equation 1,
B is an amount of incident light provided to the composite, and
B′ is an amount of incident light passing through the composite,
A light conversion efficiency (CE) (e.g., an external quantum efficiency or an internal quantum efficiency) of the composite may be greater than or equal to about 50%, greater than or equal to about 55%, greater than or equal to about 60%, greater than or equal to about 65%, greater than or equal to about 70%, or greater than or equal to about 75%:

$$Internal quantum efficiency ( \% ) = [ A / ( B - {B}^{′} ) ] \times 100 \qquad Equation 2$$

$$External quantum efficiency ( \% ) = [ A / B ] \times 100 \qquad Equation 3$$

wherein:
A: amount of the first light emitted from the composite
B: amount of the irradiated incident light
B′: amount of the incident light passing through the composite.

In an embodiment, the composite may be prepared from an ink composition, The ink composition may include a liquid vehicle; and a plurality of the semiconductor nanoparticles of an embodiment. The semiconductor nanoparticle may be dispersed in the liquid vehicle.

The liquid vehicle may include a liquid monomer, an organic solvent, or a combination thereof. The ink composition may further include metal oxide nanoparticle(s) e.g., dispersed in the liquid vehicle. The ink composition may further include a dispersant (for dispersing the nanoparticles and/or the metal oxide nanoparticles). The dispersant may include a carboxylic acid group-containing organic compound (a monomer or a polymer). The liquid vehicle may not include an (e.g., volatile) organic solvent. The ink composition may be a solvent-free system.

The liquid monomer may include a (photo)polymerizable monomer including a carbon-carbon double bond. The composition may optionally further include a (thermal or photo) initiator. The polymerization of the composition may be initiated by light or heat.

Details of the semiconductor nanoparticle(s) in the composition (or composite) are as described herein. An amount of the semiconductor nanoparticle in the composition (or composite) may be appropriately adjusted in consideration of a desired end use (e.g., a color filter, or the like). In an embodiment, an amount of the semiconductor nanoparticle in the composition (or composite) may be greater than or equal to about 1 weight percent (wt %), for example, greater than or equal to about 2 wt %, greater than or equal to about 3 wt %, greater than or equal to about 4 wt %, greater than or equal to about 5 wt %, greater than or equal to about 6 wt %, greater than or equal to about 7 wt %, greater than or equal to about 8 wt %, greater than or equal to about 9 wt %, greater than or equal to about 10 wt %, greater than or equal to about 15 wt %, greater than or equal to about 20 wt %, greater than or equal to about 25 wt %, greater than or equal to about 30 wt %, greater than or equal to about 35 wt %, or greater than or equal to about 40 wt % based on the solid content of the composition or composite (hereinafter, the solid content may be a solid content of the composition or a solid content of the composite), The amount of the semiconductor nanoparticle may be less than or equal to about 70 wt %, for example, less than or equal to about 65 wt %, less than or equal to about 60 wt %, less than or equal to about 55 wt %, or less than or equal to about 50 wt %, based on the solid content of the composition or composite. A weight percentage of a given component with respect to a total solid content in a composition may represent an amount of the given component in the composite described herein.

In an embodiment, an ink composition may be a semiconductor nanoparticle-containing photoresist composition applicable in a photolithography manner. In an embodiment, an ink composition may be a semiconductor nanoparticle-containing composition capable of providing a pattern in a printing manner (e.g., a droplet discharging method such as an inkjet printing). The composition according to an embodiment may not include a conjugated (or conductive) polymer (except for a cardo binder to be described herein). The composition according to an embodiment may include a conjugated polymer. Herein, the conjugated polymer refers to a polymer (e.g., polyphenylenevinylene, or the like) having a conjugated double bond in the main chain.

In the composition according to an embodiment, the dispersant may ensure dispersibility of the semiconductor nanoparticles. In an embodiment, the dispersant may be a binder (or a binder polymer). The binder may include a carboxylic acid group (e.g., in the repeating unit). The binder may be an insulating polymer. The binder may be a carboxylic acid group-containing compound (a monomer or a polymer).

In the composition (or the composite), an amount of the dispersant may be greater than or equal to about 0.5 wt %, for example, greater than or equal to about 1 wt %, greater than or equal to about 5 wt %, greater than or equal to about 10 wt %, greater than or equal to about 15 wt %, or greater than or equal to about 20 wt %, based on the total solid content of the composition (or composite). The amount of the dispersant may be less than or equal to about 55 wt %, less than or equal to about 35 wt %, less than or equal to about 33 wt %, or less than or equal to about 30 wt %, based on the total solid content of the composition (or composite).

In the composition (or liquid vehicle), a liquid monomer or a polymerizable (e.g., photopolymerizable) monomer (hereinafter, referred to as a monomer) including the carbon-carbon double bond may include a (e.g., photopolymerizable) (meth)acryl-containing monomer. The monomer may be a precursor for an insulating polymer.

An amount of the (photopolymerizable) monomer, based on a total weight or a total solid content of the composition, may be greater than or equal to about 0.5 wt %, for example, greater than or equal to about 1 wt %, greater than or equal to about 2 wt %, greater than or equal to about 3 wt %, greater than or equal to about 5 wt %, or greater than or equal to about 10 wt %. An amount of the (photopolymerizable) monomer, based on a total weight or a total solid content of the composition, may be less than or equal to about 30 wt %, for example, less than or equal to about 28 wt %, less than or equal to about 25 wt %, less than or equal to about 23 wt %, less than or equal to about 20 wt %, less than or equal to about 18 wt %, less than or equal to about 17 wt %, less than or equal to about 16 wt %, or less than or equal to about 15 wt %.

The (photo)initiator included in the composition may be used for (photo)polymerization of the aforementioned monomer. The initiator is a compound accelerating a radical reaction (e.g., radical polymerization of monomer) by producing radical chemical species under a mild condition (e.g., by heat or light). The initiator may be a thermal initiator or a photoinitiator. The initiator is not particularly limited and may be appropriately selected.

In the composition, an amount of the initiator may be appropriately adjusted considering types and amounts of the polymerizable monomers. In an embodiment, the amount of the initiator may be greater than or equal to about 0.01 wt %, for example, greater than or equal to about 1 wt %, and less than or equal to about 10 wt %, for example, less than or equal to about 9 wt %, less than or equal to about 8 wt %, less than or equal to about 7 wt %, less than or equal to about 6 wt %, or less than or equal to about 5 wt %, based on the total weight of the composition (or the total weight of the solid amount), but is not limited thereto.

The composition (or composite) may further include a (multi- or monofunctional) thiol compound having at least one thiol group at the terminal end (or a moiety derived therefrom, such as a moiety produced by a reaction between a thiol and a carbon-carbon double bond, for example, a sulfide group), a metal oxide fine particle (e.g., a metal oxide nanoparticle), or a combination thereof.

The metal oxide fine particle may include TiO₂, SiO₂, BaTiO₃, Ba₂TiO₄, ZnO, or a combination thereof. In the composition (or composite), an amount of the metal oxide fine particle may be greater than or equal to about 1 wt %, greater than or equal to about 2 wt %, greater than or equal to about 3 wt %, greater than or equal to about 5 wt %, or greater than or equal to about 10 wt % and less than or equal to about 50 wt %, less than or equal to about 40 wt %, less than or equal to about 30 wt %, less than or equal to about 25 wt %, less than or equal to about 20 wt %, less than or equal to about 15 wt %, less than or equal to about 10 wt %, less than or equal to about 7 wt %, less than or equal to about 5 wt %, or less than or equal to about 3 wt %, based on the total solid content.

A diameter of the metal oxide fine particle is not particularly limited, and may be appropriately selected. The diameter of the metal oxide fine particle may be greater than or equal to about 100 nm, for example greater than or equal to about 150 nm, or greater than or equal to about 200 nm and less than or equal to about 1000 nm, or less than or equal to about 800 nm.

The polythiol compound may be a dithiol compound, a trithiol compound, a tetrathiol compound, or a combination thereof. For example, the thiol compound may be ethylene glycol bis(3-mercaptopropionate), ethylene glycol dimercapto acetate, trimethylolpropane tris(3-mercaptopropionate), pentaerythritol tetrakis(3-mercaptopropionate), pentaerythritol tetrakis(2-mercaptoacetate), 1,6-hexanedithiol, 1,3-propanedithiol, 1,2-ethanedithiol, polyethylene glycol dithiol including 1 to 10 ethylene glycol repeating units, or a combination thereof.

An amount of the thiol compound (or moieties derived therefrom) may be less than or equal to about 50 wt %, less than or equal to about 40 wt %, less than or equal to about 30 wt %, less than or equal to about 20 wt %, less than or equal to about 10 wt %, less than or equal to about 9 wt %, less than or equal to about 8 wt %, less than or equal to about 7 wt %, less than or equal to about 6 wt %, or less than or equal to about 5 wt %, based on the total solid content of the composition (or composite). The amount of the thiol compound may be greater than or equal to about 0.1 wt %, for example, greater than or equal to about 0.5 wt %, greater than or equal to about 1 wt %, greater than or equal to about 5 wt %, greater than or equal to about 10 wt %, greater than or equal to about 15 wt %, greater than or equal to about 18 wt %, or greater than or equal to about 20 wt %, based on the total solid content of the composition (or composite).

The composition or the liquid vehicle may include an organic solvent. In some embodiments, the composition or the liquid vehicle may not include an organic solvent. If present, the type of organic solvent that may be used is not particularly limited. The type and amount of the organic solvent is appropriately determined in consideration of the types and amounts of the aforementioned main components (i.e., nanoparticles, dispersants, polymerizable monomers, initiators, thiol compounds, or the like, if present) and other additives to be described herein, The composition may include a solvent in a residual amount except for a desired amount of the (non-volatile) solid. In an embodiment, examples of the organic solvent may be an ethylene glycols such as ethylene glycol, diethylene glycol, polyethylene glycol, and the like; a glycol ether solvent such as ethylene glycol monomethylether, ethylene glycol monoethyl ether, diethylene glycol monomethyl ether, ethylene glycol diethyl ether, diethylene glycol dimethyl ether, or the like; a glycol ether acetate solvent such as ethylene glycol acetate, ethylene glycol monoethyl ether acetate, diethylene glycol monoethyl ether acetate, diethylene glycol monobutyl ether acetate, or the like; a propylene glycol solvent such as propylene glycol, or the like; a propylene glycol ether solvent such as propylene glycol monomethyl ether, propylene glycol monoethyl ether, propylene glycol monopropyl ether, propylene glycol monobutyl ether, propylene glycol dimethyl ether, dipropylene glycol dimethyl ether, propylene glycol diethyl ether, dipropylene glycol diethyl ether, or the like; a propylene glycol ether acetate solvent such as propylene glycol monomethyl ether acetate, dipropylene glycol monoethyl ether acetate, or the like; an amide solvent such as N-methylpyrrolidone, dimethyl formamide, dimethyl acetamide, or the like; a ketone solvent such as methylethylketone (MEK), methylisobutylketone (MIBK), cyclohexanone, or the like; a petroleum solvent such as toluene, xylene, solvent naphtha, or the like; an ester solvent such as ethyl acetate, butyl acetate, ethyl lactate, ethyl 3-ethoxy propionate, or the like; an ether solvent such as diethyl ether, dipropyl ether, dibutyl ether, or the like; chloroform, a C1 to C40 aliphatic hydrocarbon solvent (e.g., alkane, alkene, or alkyne), a halogen (e.g., chloro) substituted C1 to C40 aliphatic hydrocarbon solvent (e.g., dichloroethane, trichloromethane, or the like), a C6 to C40 aromatic hydrocarbon solvent (e.g., toluene, xylene, or the like), a halogen (e.g., chloro) substituted C6 to C40 aromatic hydrocarbon solvent; or a combination thereof.

In addition to the aforementioned components, the composition (or composite) of an embodiment may further include an additive such as a light diffusing agent, a leveling agent, a coupling agent, or a combination thereof, Components (binder, monomer, solvent, additives, thiol compound, cardo binder, or the like) included in the composition of an embodiment may be appropriately selected, and for specific details thereof, for example, US-2017-0052444-A1 may be referred to, which is incorporated herein in its entirety.

In the preparation of the composition according to an embodiment, each of the above-described components may be manufactured sequentially or simultaneously mixed, and the order thereof is not particularly limited.

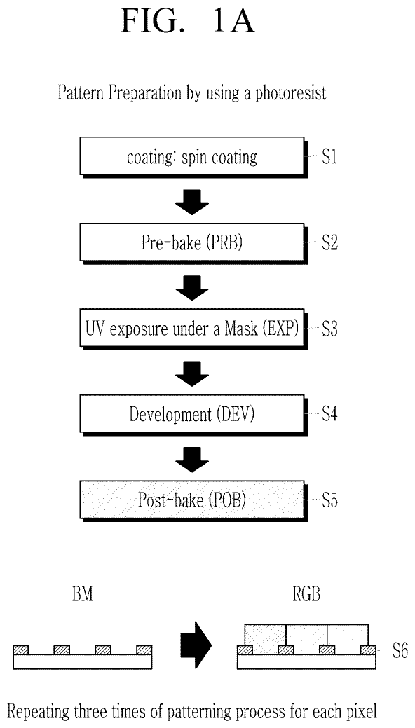

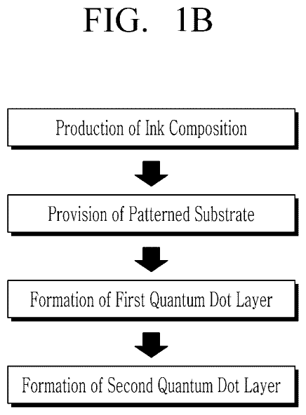

The composition may provide a color conversion layer (or a patterned film of the composite) by (e.g., radical) polymerization. The color conversion layer (or the patterned film of the composite) may be produced using a photoresist composition. Referring to FIG. 1A, this method may include forming a film of the aforementioned composition on a substrate (S1); prebaking the film according to selection (S2); exposing a selected region of the film to light (e.g., having a wavelength of less than or equal to about 400 nm) (S3); and developing the exposed film with an alkali developing solution to obtain a pattern of a quantum dot-polymer composite (also may be referred as to “nanoparticle-polymer composite”, “semiconductor nanoparticle composite” or “composite”) (S4).

Referring to FIG. 1A, the aforementioned composition may be applied to a predetermined thickness on a substrate using an appropriate method such as spin coating or slit coating to form a film. The formed film may be optionally subjected to a pre-baking (PRB) step. The pre-baking may be performed by selecting an appropriate condition from known conditions of a temperature, time, an atmosphere, or the like.

The formed (or optionally prebaked) film is exposed to light having a predetermined wavelength under a mask having a predetermined pattern (EXP). A wavelength and intensity of the light may be selected considering types and amounts of the photoinitiator, types and amounts of the quantum dots, or the like.

The exposed film may then be treated with an alkali developing solution (e.g., dipping or spraying) to dissolve an unexposed region and obtain a desired pattern (DEV). The obtained pattern may be, optionally, post-exposure baked (POB) to improve crack resistance and solvent resistance of the pattern, for example, at a temperature of about 150° C. to about 230° C. for a predetermined time (e.g., greater than or equal to about 10 minutes, or greater than or equal to about 20 minutes) (S5).

When the color conversion layer or the patterned film of the semiconductor nanoparticle composite has a plurality of repeating sections (that is, color conversion regions), each repeating section may be formed by preparing a plurality of compositions including quantum dots (e.g., red light emitting quantum dots, green light emitting quantum dots, or optionally, blue light emitting quantum dots) having desired luminous properties (photoluminescence peak wavelength or the like) and repeating the aforementioned pattern-forming process as many times as necessary (e.g., 2 times or more, or 3 times or more) for each composition, resultantly obtaining a nanoparticle-polymer composite having a desired pattern (S6). For example, the nanoparticle-polymer composite may have a pattern of at least two repeating color sections (e.g., RGB color sections). This pattern of the nanoparticle-polymer composite may be used as a photoluminescence type color filter in a display device.

The color conversion layer or patterned film of the semiconductor nanoparticle composite may be produced using an ink composition configured to form a pattern in an inkjet manner. Referring to FIG. 1B, such a method may include preparing an ink composition according to an embodiment, providing a substrate (e.g., with pixel areas patterned by electrodes and optionally banks or trench-type partition walls, or the like), and depositing an ink composition on the substrate (or the pixel area) to form, for example, a first composite layer (or first region). The method may include depositing an ink composition on the substrate (or the pixel area) to form, for example, a second composite layer (or second region). The first and second composite layers may be first and second quantum dot layers, respectively. The forming of the first composite layer and forming of the second composite layer may be simultaneously or sequentially performed,

The depositing of the ink composition may be performed using an appropriate liquid drop discharger, for example an inkjet or nozzle printing system (having an ink storage and at least one print head). The deposited ink composition may provide a (first or second) composite layer through the solvent removal and polymerization by the heating. The method may provide a highly precise nanoparticle-polymer composite film or patterned film for a short time by the simple method.

In the nanoparticle-polymer composite (e.g., first composite) of an embodiment, the (polymer) matrix may include the components described herein with respect to the composition. In the composite, an amount of the matrix, based on a total weight of the composite, may be greater than or equal to about 10 wt %, greater than or equal to about 20 wt %, greater than or equal to about 30 wt %, greater than or equal to about 40 wt %, greater than or equal to about 50 wt %, or greater than or equal to about 60 wt %. The amount of the matrix may be, based on a total weight of the composite, less than or equal to about 95 wt %, less than or equal to about 90 wt %, less than or equal to about 80 wt %, less than or equal to about 70 wt %, less than or equal to about 60 wt %, or less than or equal to about 50 wt %.

The (polymer) matrix may include a dispersant (e.g., a carboxylic acid group-containing binder polymer), a polymerization product (e.g., an insulating polymer) of a polymerizable monomer including (at least one, for example, at least two, at least three, at least four, or at least five) carbon-carbon double bonds, a polymerization product of the polymerizable monomer and a polythiol compound having at least two thiol groups (e.g., at a terminal end), or a combination thereof. The matrix may include a linear polymer, a crosslinked polymer, or a combination thereof. The (polymer) matrix may not include a conjugated polymer (excluding cardo resin). The matrix may include a conjugated polymer.

The crosslinked polymer may include a thiol-ene resin, a crosslinked poly(meth)acrylate, a crosslinked polyurethane, a crosslinked epoxy resin, a crosslinked vinyl polymer, a crosslinked silicone resin, or a combination thereof. In an embodiment, the crosslinked polymer may be a polymerization product of the aforementioned polymerizable monomers and optionally a polythiol compound.

The linear polymer may include a repeating unit derived from a carbon-carbon unsaturated bond (e.g., a carbon-carbon double bond). The repeating unit may include a carboxylic acid group. The linear polymer may include an ethylene repeating unit.

The carboxylic acid group-containing repeating unit may include a unit derived from a monomer including a carboxylic acid group and a carbon-carbon double bond, a unit derived from a monomer having a dianhydride moiety, or a combination thereof.

The (polymer) matrix may include a carboxylic acid group-containing compound (e.g., a binder, a binder polymer, or a dispersant) (e.g., for dispersion of semiconductor nanoparticles or a binder).

The first composite (or film or pattern thereof) may have, for example, a thickness of less than or equal to about 25 micrometers (μm), less than or equal to about 20 μm, less than or equal to about 15 μm, less than or equal to about 10 μm, less than or equal to about 8 μm, or less than or equal to about 7 μm to greater than about 2 μm, for example, greater than or equal to about 3 μm, greater than or equal to about 3.5 μm, greater than or equal to about 4 μm, greater than or equal to about 5 μm, greater than or equal to about 6 μm, greater than or equal to about 7 μm, greater than or equal to about 8 μm, greater than or equal to about 9 μm, or greater than or equal to about 10 μm.

The semiconductor nanoparticle(s), the composite (or pattern thereof) including the semiconductor nanoparticle(s), or a color conversion panel including the same may be included in an electronic device, Such an electronic device may include a display device, a light emitting diode (LED), an organic light emitting diode (OLED), a quantum dot LED, a sensor, a solar cell, an imaging sensor, a photodetector, or a liquid crystal display device, but embodiments are not limited thereto. The aforementioned quantum dot may be included in an electronic apparatus. Such an electronic apparatus may include, but is not limited to, a portable terminal device, a monitor, a notebook PC, a television, an electric sign board, a camera, a car, or the like, but embodiments are not limited thereto. The electronic apparatus may be a portable terminal device, a monitor, a laptop personal computer, or a television including a display device (or a light emitting device) including quantum dots. The electronic apparatus may be a camera or a mobile terminal device including an image sensor including quantum dots, The electronic apparatus may be a camera or a vehicle including a photodetector including quantum dots.

An embodiment provides a color conversion layer (e.g., a color conversion structure or a color conversion panel) including a color conversion region including the semiconductor nanoparticle described herein. The color conversion panel may include a color conversion layer including a color conversion region and optionally a partition wall defining each region of the color conversion layer. The color conversion region may include a first region corresponding to a first pixel, and the first region may include the semiconductor nanoparticles or the composite. In the color conversion panel of an embodiment, the composite may be in the form of a patterned film. In another embodiment, the composite may have a sheet form. The first region may include a first composite, and the first composite may include a matrix and semiconductor nanoparticles dispersed in the matrix and is configured to emit first light. An embodiment provides the semiconductor nanoparticles or a population thereof.

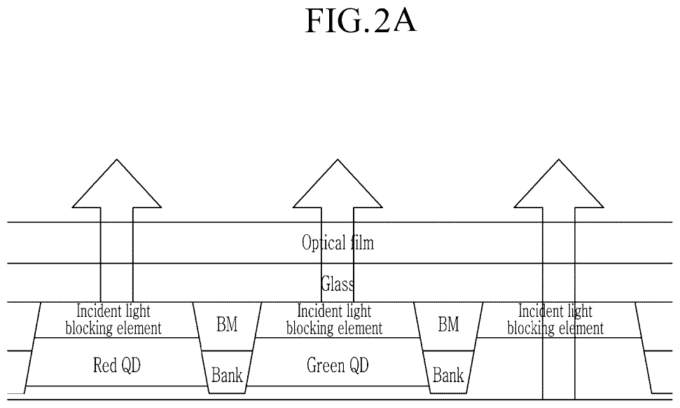

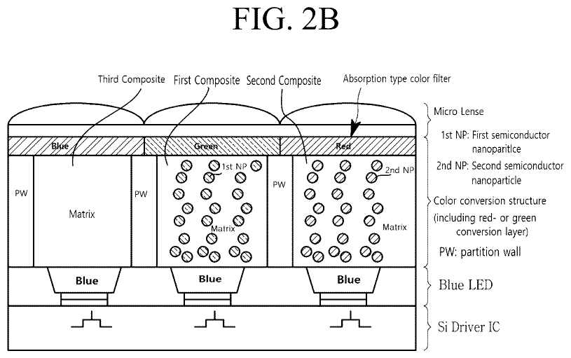

The color conversion layer (e.g., a color conversion structure) may include the composite or a patterned film thereof according to an embodiment, FIG. 2A is a schematic cross-sectional view of a color conversion panel according to an embodiment. Referring to FIG. 2A, the color conversion panel may optionally further include a partition wall (e.g., a black matrix BM, a bank, or a combination thereof) that defines each region of the color conversion layer (e.g., a color conversion structure). FIG. 2B illustrates an electronic device (a display device) including a color conversion panel and a light source according to another embodiment. In the electronic device of an embodiment, a color conversion panel including a color conversion layer or a color conversion structure may be disposed on an LED on a chip (e.g., a micro LED on a chip). Referring to FIG. 2B, a circuit (e.g., Si driver IC) configured to drive the light source may be disposed under a light source (e.g., blue LED) configured to emit incident light (e.g., a blue light). The color conversion layer may include a first composite including a semiconductor nanoparticle (or referred as to “first semiconductor nanoparticle”) emitting a first light (e.g., a green light), and a second composite including a semiconductor nanoparticle (or referred as to “second semiconductor nanoparticle”) emitting a second light (e.g., a red light), or a third composite that emits or passes a third light (e.g., incident light or a blue light). A partition wall PW (e.g., including an inorganic material such as silicon or silicon oxide, or based on an organic material) may be disposed between respective composites. The partition wall may include a trench hole, a via hole, or a combination thereof. A first optical element (e.g., an absorption type color filter) may be disposed on a light extraction surface of a color conversion layer. An additional optical element such as a micro lens may be further disposed on the first optical element.

The color conversion region may include a first region configured to emit the aforementioned first light (or red light) (e.g., by incident light irradiation). In an embodiment, the first region can correspond to a red pixel. The first region may include a first composite (e.g., a luminescent composite). The first light can be red light with an emission peak wavelength in the range of 600 nm to 650 nm (e.g., 620 nm to 650 nm). The first light or red light can have an emission peak wavelength within the wavelength range described herein. The first light or red light can refer to the semiconductor nanoparticles.

The color conversion region can further include a second region (e.g., one or more) configured to emit second light (e.g., green light) different from the first light (e.g., by excitation light irradiation). The second region can include a second composite. The semiconductor nanoparticle composite of the second region can include semiconductor nanoparticles (e.g., quantum dots) that emit light of a wavelength (e.g., different color) different from that of the semiconductor nanoparticle composite of the first region. The emission peak wavelength of the green light can be greater than or equal to about 500 nm, greater than or equal to about 501 nm, greater than or equal to about 504 nm, greater than or equal to about 505 nm, or greater than or equal to about 520 nm. The maximum emission peak wavelength of the green light can be less than or equal to about 580 nm, less than or equal to about 560 nm, less than or equal to about 550 nm, less than or equal to about 530 nm, less than or equal to about 525 nm, less than or equal to about 520 nm, less than or equal to about 515 nm, or less than or equal to about 510 nm.

The color conversion panel can further include a third region (one or more) that emits or transmits third light (e.g., blue light) different from the first light and the second light. The incident light can include the third light (e.g., blue light) and optionally green light. The third light can include blue light with an emission peak wavelength in the range of greater than or equal to about 380 nm (e.g., greater than or equal to about 440 nm, greater than or equal to about 445 nm, greater than or equal to about 450 nm, or greater than or equal to about 455 nm) and less than or equal to about 480 nm (less than or equal to about 475 nm, less than or equal to about 470 nm, less than or equal to about 465 nm, or less than or equal to about 460 nm).

In an embodiment, the color conversion panel or the color conversion layer may include a plurality of first regions, and the composite can form a predetermined pattern to be respectively disposed in the first regions of the color conversion panel. The composite (or their pattern) can be manufactured from an (ink) composition by any method, for example, photolithography or inkjet method. Therefore, an embodiment relates to a composition including semiconductor nanoparticles, which will be described in detail below.

In an embodiment, the electronic device or the display device (e.g., display panel) may further include a color conversion layer (or a color conversion panel) and optionally, a light source. The light source may provide incident light to the color conversion layer or the color conversion panel. In an embodiment, the display panel may include a light emitting panel (or a light source), the aforementioned color conversion panel, and a light transmitting layer located between the aforementioned light emitting panel and the aforementioned color conversion panel. The color conversion panel may include a substrate, and the color conversion layer may be disposed on the substrate.

When present, the light source or the light emitting panel may provide an incident light to the color conversion layer or the color conversion panel. The incident light may have a peak emission wavelength of greater than or equal to about 440 nm, for example, greater than or equal to about 450 nm, and less than or equal to about 580 nm, for example, less than or equal to about 480 nm, less than or equal to about 470 nm, or less than or equal to about 460 nm.

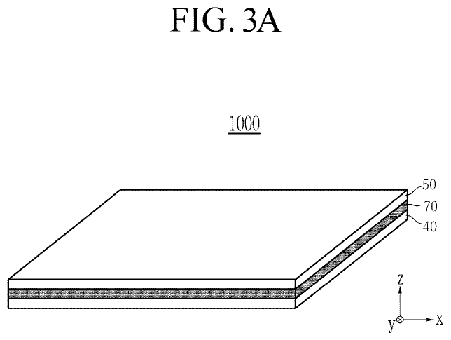

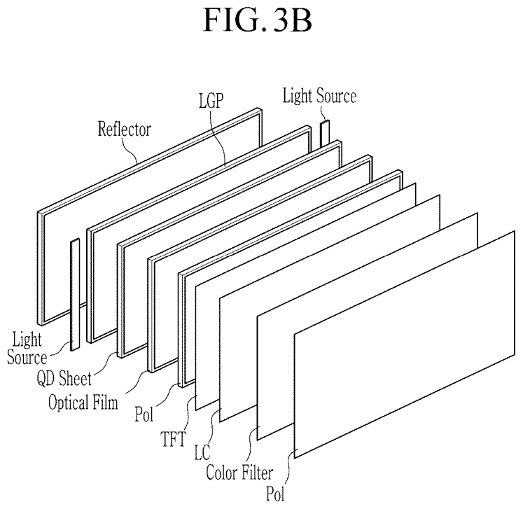

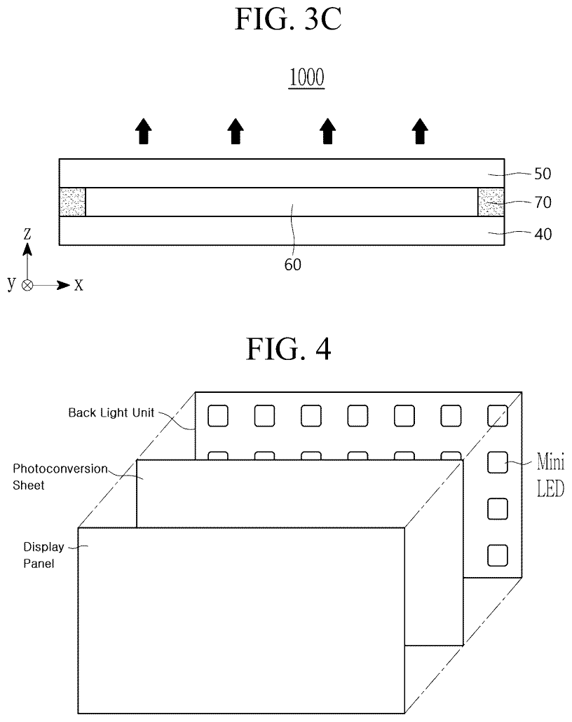

In an embodiment, the electronic device (e.g., a photoluminescent device) may further include a sheet of the semiconductor nanoparticle composite. Referring to FIG. 3B, the device 400 may include a backlight unit 410 and a liquid crystal panel 420, optionally wherein the backlight unit 410 may include a quantum dot polymer composite sheet (QD sheet). For example, the backlight unit 410 may have a structure that a reflector, a light guide plate (LGP), a light source (a blue LED or the like), the quantum dot polymer composite sheet (QD sheet), and an optical film (a prism, a double brightness enhance film (DBEF, or the like) may be stacked. The liquid crystal panel 420 may be disposed on the backlight unit 410 and have a structure where a thin film transistor (TFT), liquid crystals (LC), and a color filter are included between two polarizers (Pol). The quantum dot polymer composite sheet (QD sheet) may include semiconductor nanoparticles (e.g., quantum dots) emitting a red light and a green light after absorbing light from the light source. A blue light provided from the light source may be combined with the red light and the green light emitted from the respective semiconductor nanoparticles, while passing the quantum dot polymer composite sheet, and converted into a white light. The white light may be separated into a blue light, a green light, and a red light by a color filter in the liquid crystal panel, and then emitted to the outside for each pixel. Referring to FIG. 4, the backlight unit (BLU) may be a direct type of a BLU without a light guide plate, and may include a plurality of LEDs (e.g., mini LEDs) and a photoconversion sheet or a QD sheet may be disposed on the BLU.

The color conversion panel may include a substrate, and the color conversion layer may be disposed on the substrate. The color conversion layer or the color conversion panel may include a patterned film of the semiconductor nanoparticle composite. The patterned film may include a repeating section that is configured to emit light of a desired wavelength. The repeating section may include a second region. The second region may be a red light-emitting section. The repeating section may include a first region. The first region may be a green light-emitting section. The repeating section may include a third region. The third region may include a section that emits or transmits a blue light. Details of the first, second, and third regions are as described herein.

The light emitting panel or the light source may be an element emitting an incident light (e.g., an excitation light). The incident light may include a blue light, and, optionally, a green light. The light source may include an LED. The light source may include an organic LED (OLED). The light source may include a micro LED. On the front surface (light emitting surface) of the first region and the second region, an optical element to block (e.g., reflect or absorb) a blue light (and optionally a green light) for example, a blue light (and optionally a green light) blocking layer or a first optical filter that will be described herein may be disposed, In an embodiment, the light source may include an organic light emitting diode to emit a blue light and an organic light emitting diode to emit a green light, and a green light removing filter may be further disposed on a third region through which a blue light is transmitted.

The light emitting panel or the light source may include a plurality of light emitting units respectively corresponding to the first region and the second region, and the light emitting units may include a first electrode and a second electrode facing each other, and an (organic) electroluminescent layer located between the first electrode and the second electrode. The electroluminescent layer may include an organic light emitting material. For example, each light emitting unit of the light source may include an electroluminescent device (e.g., an organic light emitting diode (OLED)) structured to emit light of a predetermined wavelength (e.g., a blue light, a green light, or a combination thereof). Structures and materials of the electroluminescent device, specifically the organic light emitting diode (OLED) are not particularly limited.

Hereinafter, the display panel and the color conversion panel will be described in further detail with reference to the drawings.

Referring to FIGS. 3A and 3C, the display panel 1000 according to an embodiment may include a light emitting panel 40 and a color conversion panel 50. The display panel or the electronic device may further include a light transmitting layer 60 disposed between the light emitting panel 40 and the color conversion panel 50, and a binding material 70 binding the light emitting panel 40 and the color conversion panel 50. The light transmitting layer may include a passivation layer, a filling material, an encapsulation layer, or a combination thereof (not shown). A material for the light transmitting layer may be appropriately selected without particular limitation. The material for the light transmitting layer may be an inorganic material, an organic material, an organic:inorganic hybrid material, or a combination thereof.

The light emitting panel 40 and the color conversion panel 50 each may have a surface opposite the other, i.e., the two respective panels face each other, with the light transmitting layer (or the light transmitting panel) 60 disposed between the two panels. The color conversion panel 50 may be disposed in a direction such that for example, light emitting from the light emitting panel 40 irradiates the light transmitting layer 60. The binding material 70 may be disposed along edges of the light emitting panel 40 and the color conversion panel 50, and may be, for example, a sealing material.

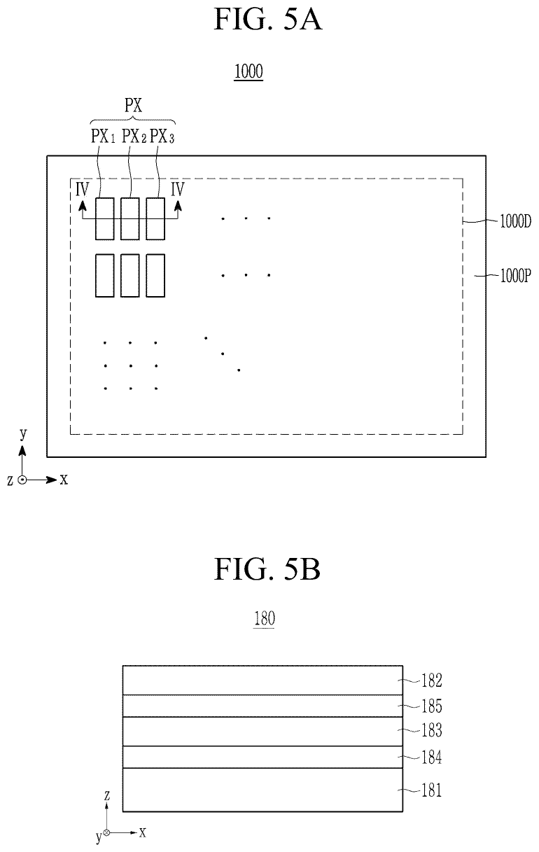

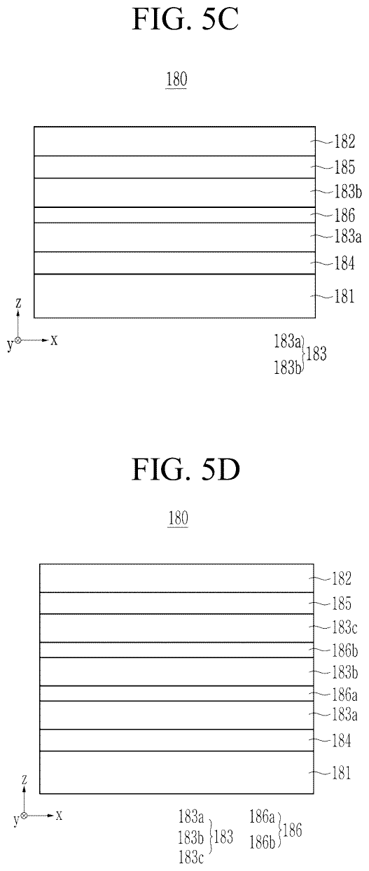

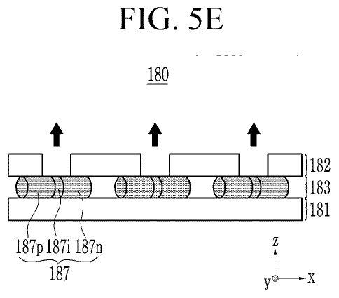

FIG. 5A is a plan view of an embodiment of a pixel arrangement of a display panel. Referring to FIG. 5A, the display panel 1000 may include a display area 1000D displaying an image and a non-display area 1000P positioned in a peripheral area of the display area 1000D and disposed with a binding material.

The display area 1000D may include a plurality of pixels PX arranged along a row (e.g., an x direction), and a column (e.g., a y direction), and each representative pixel PX may include a plurality of sub-pixels PX₁, PX₂, and PX₃ expressing, e.g., displaying, different colors from each other. An embodiment is illustrated with a structure in which three sub-pixels PX₁, PX₂, and PX₃ are configured to provide a pixel. An embodiment may further include an additional sub-pixel such as a white sub-pixel and may further include, e.g., at least one, sub-pixel expressing, e.g., displaying the same colors. The plurality of pixels PX may be aligned, for example, in a Bayer matrix, a matrix sold under the trade designation PenTile, a diamond matrix, or the like, or a combination thereof.

The sub-pixels PX₁, PX₂, and PX₃ may express, e.g., display, three primary colors or a color of a combination of three primary colors, for example, may express, e.g., display, a color of red, green, blue, or a combination thereof. For example, the first sub-pixel PX₁ may express, e.g., display, a red color, and the second sub-pixel PX₂ may express, e.g., display, a green color, and the third sub-pixel PX₃ may express, e.g., display, a blue color.

In the drawing, all sub-pixels are illustrated to have the same size, but these are not limited thereto, and at least one of the sub-pixels may be larger or smaller than other sub-pixels. In the drawing, all sub-pixels are illustrated to have the same shape, but it is not limited thereto and at least one of the sub-pixels may have different shape from the other sub-pixels.

In the display panel or electronic device according to an embodiment, the light emitting panel may include a substrate and a TFT (e.g., an oxide-containing TFT, or the like) disposed on the substrate. A light emitting device (e.g., having a tandem structure, or the like) may be disposed on the TFT.

The light emitting device may include a light emitting layer (e.g., a blue light emitting layer, a green light emitting layer, or a combination thereof) located between the first electrode and the second electrode facing each other. A charge generation layer may be disposed between each of the light emitting layers. Each of the first electrode and the second electrode may be patterned with a plurality of electrode elements to correspond to the pixel. The first electrode may be an anode or a cathode, The second electrode may be a cathode or an anode.

The light emitting device may include an organic LED, a nanorod LED, a mini LED, a micro LED, or a combination thereof.

FIGS. 5B to 5E are cross-sectional views showing examples of light emitting devices, respectively. In an embodiment, “a mini LED” may have a size of greater than or equal to about 100 micrometers, greater than or equal to about 150 micrometers, or greater than or equal to about 200 micrometers and less than or equal to about 1 millimeter, less than or equal to about 0.5 millimeters, less than or equal to about 0.15 millimeters, or less than or equal to about 0.12 millimeters, but is not limited thereto. In an embodiment, “a micro LED” may have a size of less than about 100 micrometers, less than or equal to about 50 micrometers, or less than or equal to about 10 micrometers, The size of the micro LED may be greater than or equal to about 0.1 micrometers, greater than or equal to about 0.5 micrometers, greater than or equal to about 1 micrometer, or greater than or equal to about 5 micrometers, but is not limited thereto.

Referring to FIG. 5B, the light emitting device 180 may include a first electrode 181 and a second electrode 182 facing each other; a light emitting layer 183 located between the first electrode 181 and the second electrode 182; and optionally auxiliary layers 184 and 185 located between the first electrode 181 and the light emitting layer 183, and located between the second electrode 182 and the light emitting layer 183, respectively.

The first electrode 181 and the second electrode 182 may be disposed to face each other along a thickness direction (for example, a z direction), and any one of the first electrode 181 and the second electrode 182 may be an anode and the other may be a cathode. The first electrode 181 may be a light transmitting electrode, a semi-transparent electrode, or a reflective electrode, and the second electrode 182 may be a light transmitting electrode or a semi-transparent electrode. The light transmitting electrode or semi-transparent electrode may be, for example, made of a thin single layer or multiple layers of a metal thin film including conductive metal oxides such as indium tin oxide (ITO), indium zinc oxide (IZO), zinc oxide (ZnO), tin oxide (SnO), aluminum tin oxide (AITO), fluorine-doped tin oxide (FTO), or the like; or silver (Ag), copper (Cu), aluminum (Al), magnesium (Mg), magnesium-silver (Mg—Ag), magnesium-aluminum (Mg—Al), or a combination thereof. The reflective electrode may include a metal, a metal nitride, or a combination thereof, for example, silver (Ag), copper (Cu), aluminum (Al), gold (Au), titanium (Ti), chromium (Cr), nickel (Ni), an alloy thereof, a nitride thereof (e.g., TiN), or a combination thereof, but embodiments are not limited thereto.

The light emitting layer(s) 183 may include a first light emitting body emitting light with a blue emission spectrum, a second light emitting body emitting light with a green emission spectrum, or a combination thereof.

The blue emission spectrum may have a peak emission wavelength in a wavelength region of greater than or equal to about 400 nm to less than about 500 nm and within the range, in a wavelength region of about 410 nm to about 490 nm, about 420 nm to about 480 nm, about 430 nm to about 470 nm, about 440 nm to about 465 nm, about 445 nm to about 460 nm, or about 450 nm to about 458 nm.

The green emission spectrum may have a peak emission wavelength in a wavelength region of greater than or equal to about 500 nm to less than about 590 nm and within the range, in a wavelength region of about 510 nm to about 580 nm, about 515 nm to about 570 nm, about 520 nm to about 560 nm, about 525 nm to about 555 nm, about 530 nm to about 550 nm, or about 535 nm to about 545 nm.

For example, the light emitting layers 183 or the light emitting body included therein may include a phosphorescent material, a fluorescent material, or a combination thereof. For example, the light emitting body may include an organic light emitting body, wherein the organic light emitting body may be a low molecular compound, a polymer compound, or a combination thereof. Specific types of the phosphorescent material and the fluorescent material are not particularly limited but may be appropriately selected from known materials. For example, the light emitting body may include an inorganic light emitting body, and the inorganic light emitting body may be an inorganic semiconductor, a quantum dot, a perovskite, or a combination thereof. The inorganic semiconductor may include metal nitride, metal oxide, or a combination thereof. The metal nitride, the metal oxide, or the combination thereof may include a Group Ill metal such as aluminum, gallium, indium, thallium, or the like, a Group IV metal such as silicon, germanium, tin, or a combination thereof. In an embodiment, the light emitting body may include an inorganic light emitting body, and the light emitting device 180 may be a quantum dot light emitting diode, a perovskite light emitting diode, or a micro light emitting diode (μLED). Materials usable as the inorganic light emitting body may be selected appropriately.

In an embodiment, the light emitting device 180 may further include an auxiliary layer 184 and 185. The auxiliary layer 184 and 185 may be disposed between a first electrode 181 and a light emitting layer 183, and between a second electrode 182 and a light emitting layer 183, respectively. The auxiliary layer 184 and 185 may be a charge auxiliary layer for controlling injection and/or mobility of charges. The auxiliary layers 184 and 185 may include at least one layer or two layers, and for example, may include a hole injection layer, a hole transport layer, an electron blocking layer, an electron injection layer, an electron transport layer, a hole blocking layer, or a combination thereof. At least one of the auxiliary layers 184 and 185 may be omitted, if desired. The auxiliary layer may be formed of a material appropriately selected from materials known for an organic electroluminescent device, or the like.

The light emitting devices 180 disposed in each of the subpixels PX₁, PX₂, and PX₃ may be the same or different from each other. The light emitting devices 180 in each of the subpixels PX₁, PX₂, and PX₃ may emit a light having the same or different emission spectra. The light emitting devices 180 in each of the subpixels PX₁, PX₂, and PX₃ may emit, for example, light having a blue emission spectrum, light having a green emission spectrum, or a combination thereof. The light emitting devices 180 in each of the subpixels PX₁, PX₂, and PX₃ may be separated by a pixel defining layer (not shown).

Referring to FIG. 5C, the light emitting device 180 may be a light emitting device having a tandem structure, and may include a first electrode 181 and a second electrode 182 facing each other; a first light emitting layer 183a and a second light emitting layer 183b located between the first electrode 181 and the second electrode 182; a charge generation layer 186 located between the first light emitting layer 183a and the second light emitting layer 183b, and optionally auxiliary layers 184 and 185 located between the first electrode 181 and the first light emitting layer 183a, and/or between the second electrode 182 and the second light emitting layer 183b, respectively.

Details of the first electrode 181, the second electrode 182, and the auxiliary layers 184 and 185 are as described herein.

The first light emitting layer 183a and the second light emitting layer 183b may emit a light having the same or different emission spectra. In an embodiment, the first light emitting layer 183a or the second light emitting layer 183b may emit light having a blue emission spectrum or light having a green emission spectrum, respectively. The charge generation layer 186 may inject an electric charge into the first light emitting layer 183a and/or the second light emitting layer 183b, and may control a charge balance between the first light emitting layer 183a and the second light emitting layer 183b. The charge generation layer 186 may include, for example, an n-type layer and a p-type layer, and may include, for example, an electron transport material and/or a hole transport material including an n-type dopant and/or a p-type dopant. The charge generation layer 186 may include one layer or two or more layers.

Referring to FIG. 5D, a light emitting device 180 (having a tandem structure) may include a first electrode 181 and a second electrode 182 facing each other; a first light emitting layer 183a, a second light emitting layer 183b, and a third light emitting layer 183c located between the first electrode 181 and the second electrode 182; a first charge generation layer 186a located between the first light emitting layer 183a and the second light emitting layer 183b; a second charge generation layer 186b located between the second light emitting layer 183b and the third light emitting layer 183c; and optionally, auxiliary layers 184 and 185 located between the first electrode 181 and the first light emitting layer 183a, and/or between the second electrode 182 and the third light emitting layer 183c, respectively.

Details of the first electrode 181, the second electrode 182, and the auxiliary layers 184 and 185 are as described herein.

The first light emitting layer 183a, the second light emitting layer 183b, and the third light emitting layer 183c may emit a light having the same or different emission spectra. The first light emitting layer 183a, the second light emitting layer 183b, and the third light emitting layer 183c may emit a blue light. In an embodiment, the first light emitting layer 183a and the third light emitting layer 183c may emit light of a blue emission spectrum, and the second light emitting layer 183b may emit light of a green emission spectrum. In another embodiment, the first light emitting layer 183a and the third light emitting layer 183c may emit light of a green emission spectrum, and the second light emitting layer 183b may emit light of a blue emission spectrum.

The first charge generation layer 186a may inject an electric charge into the first light emitting layer 183a and/or the second light emitting layer 183b, and may control charge balances between the first light emitting layer 183a and the second light emitting layer 183b. The second charge generation layer 186b may inject an electric charge into the second light emitting layer 183b and/or the third light emitting layer 183c, and may control charge balances between the second light emitting layer 183b and the third light emitting layer 183c. Each of the first and second charge generation layers 186a and 186b may include one layer or two or more layers, respectively.

Referring to FIG. 5E, in an embodiment, the light emitting device 180 may include a light emitting layer 183, a first electrode 181, a second electrode 182, and a plurality of nanostructures 187 arranged in the light emitting layer 183.

One of the first electrode 181 and the second electrode 182 may be an anode and the other may be a cathode. The first electrode 181 and the second electrode 182 may be an electrode patterned according to a direction of an arrangement of the plurality of nanostructures 187, and may include, for example, a conductive oxide such as indium tin oxide (ITO), indium zinc oxide (IZO), zinc oxide (ZnO), tin oxide (SnO), aluminum tin oxide (AITO), fluorine-doped tin oxide (FTO), or the like; silver (Ag), copper (Cu), aluminum (Al), gold (Au), titanium (Ti), chromium (Cr), nickel (Ni), an alloy thereof, a nitride thereof (e.g., TiN); or a combination thereof, but embodiments are not limited thereto.

The light emitting layer 183 may include a plurality of nanostructures 187, and each of the subpixels PX₁, PX₂, and PX₃ may include a plurality of nanostructures 187. In an embodiment, the plurality of nanostructures 187 may be arranged in one direction, but embodiments are not limited thereto. The nanostructures 187 may be a compound-containing semiconductor that is configured to emit light of a predetermined wavelength for example with an application of an electric current, and may be, for example, a linear nanostructure such as a nanorod or a nanoneedle, A diameter or a long diameter of the nanostructures 187 may be, for example, several nanometers to several hundreds of nanometers, and aspect ratios of the nanostructures 187 may be greater than about 1, greater than or equal to about 1.5, greater than or equal to about 2.0, greater than or equal to about 3.0, greater than or equal to about 4.0, greater than or equal to about 4.5, greater than or equal to about 5.0, greater than about 1 to less than or equal to about 20, about 1.5 to about 20, about 2.0 to about 20, about 3.0 to about 20, about 4.0 to about 20, about 4.5 to about 20, or about 5.0 to about 20.

Each of the nanostructures 187 may include a p-type region 187p, an n-type region 187n, and a multiple quantum well region 187i, and may be configured to emit light from the multiple quantum well region 187i, The nanostructure 187 may include, for example, gallium nitride (GaN), indium gallium nitride (InGaN), aluminum gallium nitride (AlGaN), or a combination thereof, and may have, for example, a core-shell structure.

The plurality of nanostructures 187 may each emit light having the same or different emission spectra. In an embodiment, the nanostructure may emit light of a blue emission spectrum, for example, light of a blue emission spectrum having a peak emission wavelength in a wavelength region of greater than or equal to about 400 nm to less than 500 nm, about 410 nm to about 490 nm, or about 420 nm to about 480 nm.

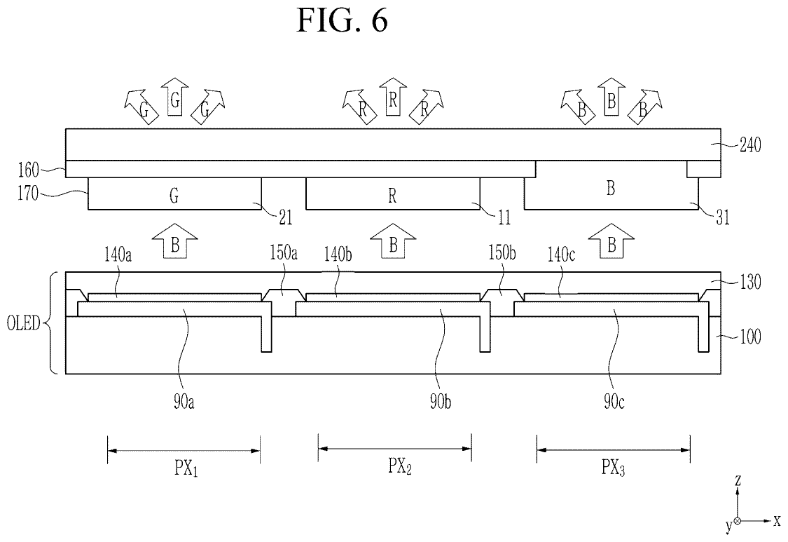

FIG. 6 is a schematic cross-sectional view of a device (or a display panel) according to an embodiment. Referring to FIG. 6, the light source (or the light emitting panel) may include an organic light emitting diode that emits a blue light (B) (and optionally a green light (G)), The organic light emitting diode (OLED) may include at least two pixel electrodes 90a, 90b, 90c formed on the substrate 100, pixel defining layers 150a, 150b formed between the adjacent pixel electrodes 90a, 90b, 90c, organic light emitting layers 140a, 140b, 140c formed on each pixel electrode 90a, 90b, 90c, and a common electrode layer 130 formed on the organic light emitting layer 140a, 140b, 140c, A thin film transistor (TFT) and a substrate may be disposed under the organic light emitting diode (OLED), which are not shown, Pixel areas of the OLED may be disposed corresponding to the first, second, and third regions described herein. In an embodiment, the color conversion panel and the light emitting panel may be separated as shown in FIG. 6. In an embodiment, the color conversion panel may be stacked directly on the light emitting panel.

A laminated structure including the luminescent nanostructure composite pattern 170 (e.g., a first region 11 or R including red light emitting luminescent nanostructures, a second region 21 or G including green light emitting luminescent nanostructures, and a third region 31 or B including or not including a luminescent nanostructure, e.g., a blue light emitting luminescent nanostructure) and the substrate 240 may be disposed on the light source. The blue light emitted from the light source enters the first region and second region and may emit a red light and a green light, respectively. The blue light emitted from the light source may pass through the third region. An element (first optical filter 160 or excitation light blocking layer) configured to block the excitation light may be disposed between the luminescent nanostructure composite layers R and G and the substrate, if desired. In an embodiment, the excitation light includes a blue light and a green light, and a green light blocking filter (not shown) may be added to the third region. The first optical filter or the excitation light blocking layer will be described in more detail herein.

Such a (display) device may be produced by separately producing the aforementioned laminated structure and LED or OLED (e.g., emitting a blue light) and then combining the laminated structure and LED or OLED. The (display) device may be produced by directly forming the luminescent nanostructure composite layer (pattern) on the LED or OLED.

In the color conversion panel or a display device, a substrate may be a substrate including an insulation material. The substrate may include glass; a polymer such as a polyester of poly(ethylene terephthalate) (PET), poly(ethylene naphthalate) (PEN), or the like, a polycarbonate, or a polyacrylate; a polysiloxane (e.g. PDMS, or the like); an inorganic material such as Al₂O₃, ZnO, or the like; or a combination thereof, but embodiments are not limited thereto. A thickness of the substrate may be appropriately selected taking into consideration a substrate material but is not particularly limited. The substrate may have flexibility. The substrate may have a transmittance of greater than or equal to about 50%, greater than or equal to about 60%, greater than or equal to about 70%, greater than or equal to about 80%, or greater than or equal to about 90% for light emitted from the semiconductor nanoparticle.

A wire layer including a thin film transistor or the like may be formed on the substrate. The wire layer may further include a gate line, a sustain voltage line, a gate insulating film, a data line, a source electrode, a drain electrode, a semiconductor layer, a protective layer, or the like. The detailed structure of the wire layer may vary depending on an embodiment. The gate line and the sustain voltage line may be electrically separated from each other, and the data line may be insulated and crossing the gate line and the sustain voltage line. The gate electrode, the source electrode, and the drain electrode may form a control terminal, an input terminal, and an output terminal of the thin film transistor, respectively. The drain electrode may be electrically connected to the pixel electrode that will be described herein.

The pixel electrode may function as an electrode (e.g., anode) of the display device. The pixel electrode may be formed of a transparent conductive material such as indium tin oxide (ITO) or indium zinc oxide (IZO). The pixel electrode may be formed of a material having a light blocking property such as gold (Au), platinum (Pt), nickel (Ni), tungsten (W), chromium (Cr), molybdenum (Mo), iron (Fe), cobalt (Co), copper (Cu), palladium (Pd), or titanium (Ti). The pixel electrode may have a two-layered structure where the transparent conductive material and the material having light blocking properties are stacked sequentially.

Between two adjacent pixel electrodes, a pixel define layer (PDL) may overlap with a terminal end of the pixel electrode to divide the pixel electrode into a pixel unit. The pixel define layer is an insulating layer which may electrically block the at least two pixel electrodes.

The pixel define layer may cover a portion of the upper surface of the pixel electrode, and the remaining region of the pixel electrode where it is not covered by the pixel define layer may provide an opening. An organic light emitting layer that will be described herein may be formed on the region defined by the opening.

The organic light emitting layer may define each pixel area by the aforementioned pixel electrode and the pixel define layer. In other words, one pixel area may be defined as an area where it is formed with one organic light emitting unit layer which is contacted with one pixel electrode divided by the pixel define layer. In the display device according to an embodiment, the organic light emitting layer may be defined as a first pixel area, a second pixel area, and a third pixel area, and each pixel area may be spaced apart from each other leaving a predetermined interval by the pixel define layer.

In an embodiment, the organic light emitting layer may emit a third light belonging to a visible light region or belonging to an ultraviolet (UV) region. Each of the first to the third pixel areas of the organic light emitting layer may emit a third light. In an embodiment, the third light may be a light having a higher energy in a visible light region, and for example, may be a blue light (and optionally a green light). In an embodiment, all pixel areas of the organic light emitting layer are designed to emit the same light, and each pixel area of the organic light emitting layer may be formed of materials that are the same or similar or may show the same or similar properties. Thus, a process of forming the organic light emitting layer may be simplified, and the display device may be easily applied for, e.g., made by, a large scale/large area process. However, the organic light emitting layer according to an embodiment is not necessarily limited thereto, but the organic light emitting layer may be designed to emit at least two different lights, e.g., at least two different colored lights.

The organic light emitting layer may include an organic light emitting unit layer in each pixel area, and each organic light emitting unit layer may further include an auxiliary layer (e.g., a hole injection layer, a hole transport layer, an electron transport layer, or the like) besides the light emitting layer.

The common electrode may function as a cathode of the display device. The common electrode may be formed of a transparent conductive material such as indium tin oxide (ITO) or indium zinc oxide (IZO). The common electrode may be formed on the organic light emitting layer and may be integrated therewith.

A planarization layer or a passivation layer (not shown) may be formed on the common electrode. The planarization layer may include a (e.g., transparent) insulating material for ensuring electrical insulation with the common electrode.

In an embodiment, the display device may further include a lower substrate, a polarizing plate disposed under the lower substrate, and a liquid crystal layer disposed between the laminated structure and the lower substrate, and in the laminated structure, the photoluminescence layer (i.e., light emitting layer) may be disposed to face the liquid crystal layer. The display device may further include a polarizing plate located between the liquid crystal layer and the light emitting layer. The light source may further include LED, and, if desired, a light guide plate.

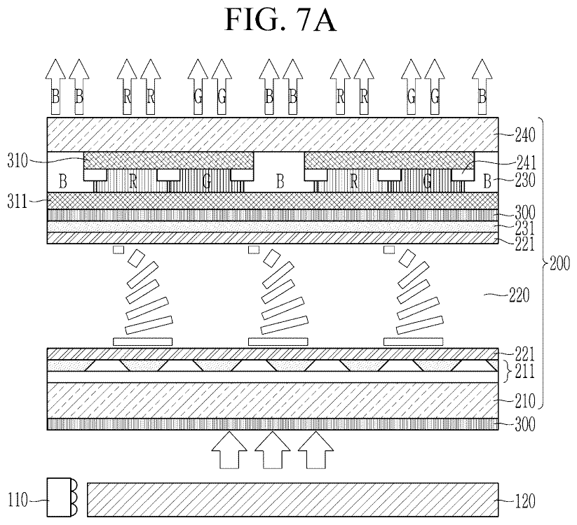

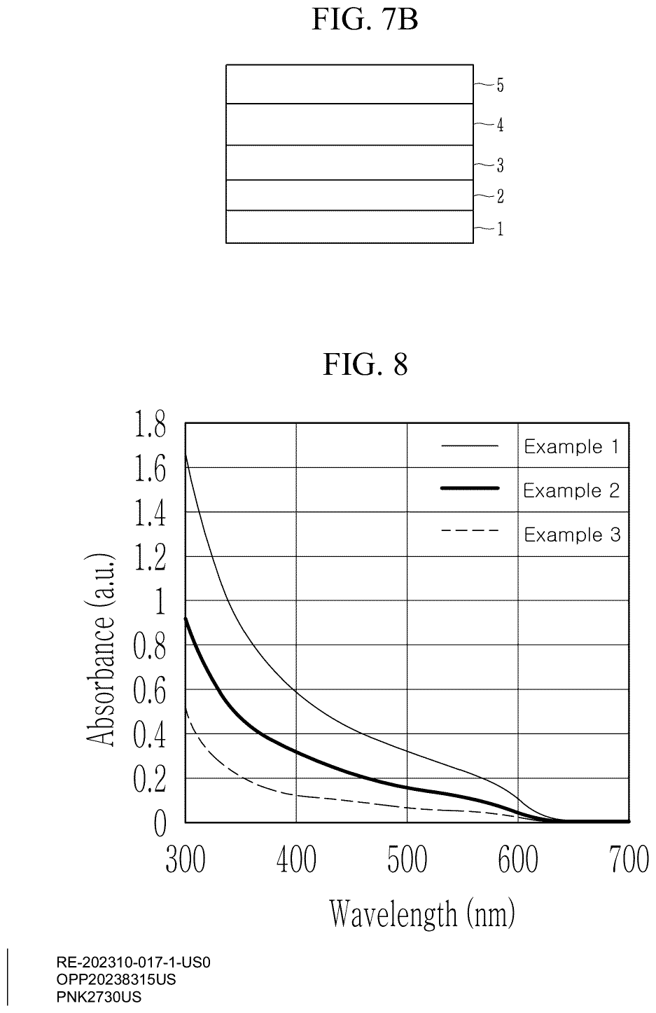

In an embodiment, the display device (e.g., a liquid crystal display device) are illustrated with a reference to a drawing, FIG. 7A is a schematic cross-sectional view showing a liquid crystal display device according to an embodiment. Referring to FIG. 7A, the display device of an embodiment may include a liquid crystal panel 200, a polarizing plate 300 disposed under the liquid crystal panel 200, and a backlight unit disposed under the polarizing plate 300.

The liquid crystal panel 200 may include a lower substrate 210, a stacked structure, and a liquid crystal layer 220 disposed between the stack structure and the lower substrate. The stack structure may include a transparent substrate 240, a first optical filter layer 310, a photoluminescent layer 230 including a pattern of a semiconductor nanoparticle polymer composite, and a second optical filter layer 311.

The lower substrate 210, also referred to as an array substrate, may be a transparent insulating material substrate. The substrate may be as described herein. A wire plate 211 may be provided on an upper surface of the lower substrate 210. The wire plate 211 may include a plurality of gate lines (not shown) and data lines (not shown) that define a pixel area, a thin film transistor disposed adjacent to a crossing region of gate lines and data lines, and a pixel electrode for each pixel area, but embodiments are not limited thereto. Details of such a wire plate are not particularly limited.

A liquid crystal layer 220 may be provided on the wire plate 211. The liquid crystal panel 200 may include an alignment layer 221 on and under the liquid crystal layer 220 to initially align the liquid crystal material included therein. Details (e.g., a liquid crystal material, an alignment layer material, a method of forming liquid crystal layer, a thickness of liquid crystal layer, or the like) of the liquid crystal layer and the alignment layer are not particularly limited.

A lower polarizing plate 300 may be provided under the lower substrate. Materials and structures of the polarizing plate 300 are not particularly limited. A backlight unit (e.g., emitting a blue light) may be disposed under the polarizing plate 300. An upper optical element or the polarizing plate 300 may be provided between the liquid crystal layer 220 and the transparent substrate 240, but is not limited thereto. For example, the upper polarizing plate may be disposed between the liquid crystal layer 220 and the photoluminescent layer 230. The polarizing plate may be any polarizer that may be used in a liquid crystal display device. The polarizing plate may be triacetyl cellulose (TAC) having a thickness of less than or equal to about 200 μm, but is not limited thereto. In another embodiment, the upper optical element may be a coating that controls a refractive index without a polarization function.

The backlight unit includes a light source 110. The light source may emit a blue light or a white light. The light source may include, but is not limited to, a blue LED, a white LED, a white OLED, or a combination thereof.

The backlight unit may further include a light guide plate 120. In an embodiment, the backlight unit may be of an edge type. For example, the backlight unit may include a reflector (not shown), a light guide plate (not shown) provided on the reflector and providing a planar light source to the liquid crystal panel 200, and/or at least one optical sheet (not shown) on the light guide plate, for example, a diffusion plate, a prism sheet, and the like, but the present disclosure is not limited thereto. The backlight unit may not include a light guide plate. In an embodiment, the backlight unit may be direct lighting. For example, the backlight unit may have a reflector (not shown) and a plurality of fluorescent lamps on the reflector at regular intervals, or may have an LED operating substrate on which a plurality of light emitting diodes, a diffusion plate thereon, and optionally at least one optical sheet may be disposed. Details (e.g., each component of a light emitting diode, a fluorescent lamp, a light guide plate, various optical sheets, and a reflector) of such a backlight unit are known and are not particularly limited.

A black matrix 241 may be provided under the transparent substrate 240 and may have openings and hide a gate line, a data line, and a thin film transistor of the wire plate on the lower substrate. For example, the black matrix 241 may have a grid shape. The photoluminescent layer 230 may be provided in the opening of the black matrix 241 and have a nanoparticle-polymer composite pattern including a first region R configured to emit a first light (e.g., a red light), a second region G configured to emit a second light (e.g., a green light), and a third region B configured to emit/transmit a third light, for example a blue light. If desired, the photoluminescent layer may further include at least one fourth region. The fourth region may include a quantum dot that emits light of a different color from the light emitted from the first to third regions (e.g., cyan, magenta, and yellow light).

In the photoluminescent layer 230, sections forming the pattern may be repeated corresponding to pixel areas formed on the lower substrate. A transparent common electrode 231 may be provided on the photoluminescent layer 230.

The third region (B) configured to emit/transmit a blue light may be a transparent color filter that does not change the emission spectrum of the light source. In this case, the blue light emitted from the backlight unit may enter in a polarized state and may be emitted through the polarizing plate and the liquid crystal layer as is. If needed, the third region may include a quantum dot emitting a blue light.

As described herein, if desired, the display device or light emitting device according to an embodiments may further include an excitation light blocking layer or a first optical filter layer (hereinafter, referred to as a first optical filter layer). The first optical filter layer may be disposed between the bottom surface of the first region (R) and the second region (G) and the substrate (e.g., the upper substrate 240) or on the upper surface of the substrate. The first optical filter layer may be a sheet having an opening in a portion corresponding to a pixel area (third region) displaying blue, and thus may be formed in portions corresponding to the first and second regions. That is, the first optical filter layer may be integrally formed at positions other than the position overlapped with the third region as shown in FIGS. 1A, 1B, 6 and/or 7A, but is not limited thereto. Two or more first optical filter layers may be spaced apart from each other at positions overlapped with the first and second regions, and optionally, the third region. When the light source includes a green light emitting device, a green light blocking layer may be disposed on the third region.

The first optical filter layer may block light, for example, in a predetermined wavelength region in the visible light region and may transmit light in the other wavelength regions, and for example, it may block a blue light (or a green light) and may transmit light except the blue light (or the green light). The first optical filter layer may transmit, for example, a green light, a red light, and/or a yellow light that is a mixed color thereof. The first optical filter layer may transmit a blue light and block a green light, and may be disposed on the blue light emitting pixel.

The first optical filter layer may substantially block excitation light and transmit light in a desired wavelength region. The transmittance of the first optical filter layer for the light in a desired wavelength range may be greater than or equal to about 70%, greater than or equal to about 80%, greater than or equal to about 90%, or even about 100%.

The first optical filter layer configured to selectively transmit a red light may be disposed at a position overlapped with the red light emitting section, and the first optical filter layer configured to selectively transmit a green light may be disposed at a position overlapped with the green light emitting section. The first optical filter layer may include a first filter region that blocks (e.g., absorbs) the blue light and the red light and selectively transmits light of a predetermined range (e.g., greater than or equal to about 500 nm, greater than or equal to about 510 nm, or greater than or equal to about 515 nm to less than or equal to about 550 nm, less than or equal to about 545 nm, less than or equal to about 540 nm, less than or equal to about 535 nm, less than or equal to about 530 nm, less than or equal to about 525 nm, or less than or equal to about 520 nm); a second filter region that blocks (e.g., absorbs) a blue light and a green light and selectively transmits light of a predetermined range (e.g., greater than or equal to about 600 nm, greater than or equal to about 610 nm, or greater than or equal to about 615 nm to less than or equal to about 650 nm, less than or equal to about 645 nm, less than or equal to about 640 nm, less than or equal to about 635 nm, less than or equal to about 630 nm, less than or equal to about 625 nm, or less than or equal to about 620 nm); or the first filter region and the second filter region. In an embodiment, the light source may emit a blue and a green mixed light, and the first optical filter layer may further include a third filter region that selectively transmits a blue light and blocks a green light.

The first filter region may be disposed at a position overlapped with the green light emitting section. The second filter region may be disposed at a position overlapped with the red light emitting section. The third filter region may be disposed at a position overlapped with the blue light emitting section.

The first filter region, the second filter region, and, optionally, the third filter region may be optically isolated. Such a first optical filter layer may contribute to improvement of color purity of the display device.

The display device may further include a second optical filter layer (e.g., a recycling layer of red/green light or yellow light) that is disposed between the photoluminescent layer and the liquid crystal layer (e.g., between the photoluminescent layer and the upper polarizing plate), transmits at least a portion of the third light (excitation light), and reflects at least a portion of the first light and/or the second light, The first light may be a red light, the second light may be a green light, and the third light may be a blue light. The second optical filter layer may transmit only the third light (B) in a blue light wavelength region having a wavelength region of less than or equal to about 500 nm and light in a wavelength region of greater than about 500 nm, which is green light (G), yellow light, red light (R), or the like, may be not passed through the second optical filter layer and reflected. The reflected green light and red light may pass through the first and second regions to be emitted to the outside of the display device.

The second optical filter layer or the first optical filter layer may be formed as an integrated layer having a relatively planar surface.

The first optical filter layer may include a polymer thin film that includes a dye and/or a pigment, which absorbs light in a wavelength that is to be blocked. The second optical filter layer or the first optical filter layer may include a single layer having a low refractive index, and may be, for example, a transparent thin film having a refractive index of less than or equal to about 1.4, less than or equal to about 1.3, or less than or equal to about 1.2. The second optical filter layer or the first optical filter layer having a low refractive index may include, for example, a porous silicon oxide, a porous organic material, a porous organic-inorganic composite, or the like, or a combination thereof.

The first optical filter layer or the second optical filter layer may include a plurality of layers having different refractive indexes. The first optical filter layer or the second optical filter layer may be formed by laminating two layers having different refractive indexes. For example, the first/second optical filter layer may be formed by alternately laminating a material having a high refractive index and a material having a low refractive index.

In an embodiment, the electronic device may include a light emitting device (e.g., an electroluminescent device) including the semiconductor nanoparticles described above, FIG. 7B is a schematic cross-sectional view of a light emitting device (electroluminescent device) according to an embodiment. Referring to FIG. 7B, the light emitting device may include an anode 1 and a cathode 5 facing each other; a quantum dot light emitting layer 3, including a plurality of quantum dots, disposed between the anode and the cathode; and a hole auxiliary layer 2 located between the anode and the quantum dot light emitting layer. The hole auxiliary layer may further include a hole injecting layer (HIL), a hole transporting layer (HTL), an electron blocking layer (EBL), or a combination thereof. The hole auxiliary layer may include any organic/inorganic material having hole characteristics. The quantum dot light emitting device may further include an electron auxiliary layer 4 located between the cathode and the quantum dot light emitting layer. The electron auxiliary layer may include an electron injecting layer (EIL), an electron transporting layer (ETL), a hole blocking layer (HBL), or a combination thereof, The electron auxiliary layer may include any organic/inorganic material having electronic properties.

Hereinafter, the exemplary embodiments are illustrated in further detail with reference to examples, However, embodiments of the present disclosure are not limited to the examples.

### EXAMPLES

### Analysis Methods

### [1] Photoluminescence Analysis

A photoluminescence (PL) spectrum of the semiconductor nanoparticles produced and a composite including the semiconductor nanoparticles was obtained using a Hitachi F-7000 spectrophotometer at an excitation wavelength of 450 nm.

The absolute quantum yield is measured using QE-2100, Otsuka.

### [2] Elemental Amount Analysis and Production Yield Calculation

Inductively coupled plasma atomic emission spectroscopy (ICP-AES) was performed using a Shimadzu ICPS-8100.

### [3] Optical Density Measurement and UV-Visibility Spectrometry Analysis

(1) A sample dispersion solution was obtained by dispersing a predetermined amount of semiconductor nanoparticles in toluene and, optionally, diluting by n times. The sample dispersion solution was placed in a cuvette providing a light path length of 10 mm (i.e., 1 centimeter) and UV spectroscopic analysis was performed using a Shimadzu UV-2600 to obtain the UV-Visible absorption spectrum.

(2) From the obtained UV-Visible absorption spectrum, the UV absorbance at a predetermined wavelength (e.g., 450 nm) was obtained and the optical density (OD) was calculated therefrom by considering the dilution factor. The calculated optical density was divided by the weight of the semiconductor nanoparticles to obtain the OD per gram at 450 nm.

### [4] Transmission Electron Microscopy (TEM) Analysis

Transmission electron microscopy analysis of semiconductor nanoparticles was performed using a UTF30 Tecnai electron microscope.

### Example 1

A 1 M sulfur precursor solution (hereinafter referred to as the first sulfur precursor) was prepared by dispersing sulfur in oleylamine. In a 100 mL reaction flask, octadecene (ODE), silver acetate, and indium acetate were added and vacuum-treated at room temperature for 10 minutes. Subsequently, nitrogen was flowed into the reaction flask, and the first sulfur precursor, oleylamine, and dodecanethiol were added. The obtained mixture was heated at 40° C. for 5 minutes, then the temperatures was raised to 240° C. and the solution reacted for about 50 minutes. The temperature of the reaction flask was lowered to 180° C., trioctylphosphine (TOP) was added, and the mixture was cooled to room temperature.

A nonsolvent was added to the obtained mixture to facilitate precipitation of the first semiconductor nanocrystals. The obtained first semiconductor nanocrystals were recovered by centrifugation and redispersed in toluene.

The amounts of the indium precursor and the first sulfur precursor relative to 1 mole of the silver precursor were 1.6 moles and 7.1 moles, respectively.

2 milliliters (mL) of a 5.7 molar (M) gallium precursor solution (hereinafter referred to as the gallium precursor) was prepared by dissolving gallium chloride in toluene.

In a flask, 841 milligram (mg) of dimethylthiourea (DMTU) (the second sulfur precursor), oleylamine, and octadecene were added and vacuum-treated at 120° C. for 10 minutes. After replacing the inside of the reaction flask with N₂, the mixture was heated at room temperature or at an elevated temperature (e.g., 240° C. or other predetermined temperature), and then the gallium precursor and the first semiconductor nanocrystals were added. Subsequently, the reaction flask was heated to 280° C. and the solution was reacted for 70 minutes. The temperature of the reaction solution was lowered to 180° C., trioctylphosphine was added, and the mixture was cooled to room temperature. Ethanol was added as a nonsolvent to promote precipitation of the produced semiconductor nanoparticles, and the obtained semiconductor nanoparticles were recovered by centrifugation and redispersed in toluene.

ICP-AES analysis, UV-Vis absorption spectroscopy, and photoluminescence analysis were performed on the manufactured semiconductor nanoparticles, and the results are summarized in Table 1, Table 2, Table 3, and FIG. 8. It was confirmed that the quantum efficiency of the manufactured semiconductor nanoparticles was greater than or equal to about 30%.

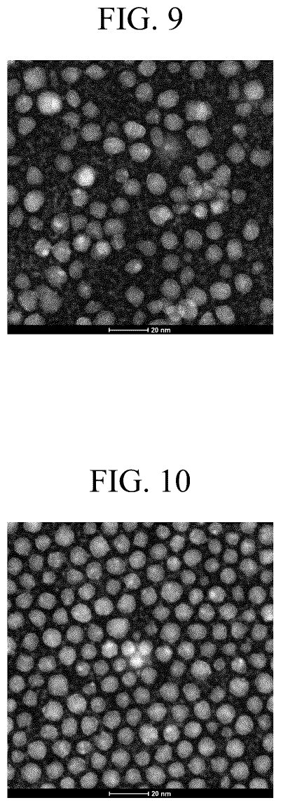

TEM analysis was performed on the manufactured semiconductor nanoparticles, and the results are shown in FIG. 9. The TEM analysis confirmed that the average size of the manufactured semiconductor nanoparticles was 8.52 nm.

### Example 2

The semiconductor nanoparticles were prepared in the same manner as in Example 1, except that the molar ratio of the precursors was slightly adjusted and the core was injected at an elevated temperature (e.g., greater than or equal to about 180° C. or 240° C.). ICP-AES analysis, UV-Vis absorption spectroscopy, and photoluminescence analysis were performed on the manufactured semiconductor nanoparticles, and the results were summarized in Table 1, Table 2, Table 3, and FIG. 8.

It was confirmed that the quantum efficiency of the manufactured semiconductor nanoparticles was greater than or equal to about 30%. It was also confirmed that the relative band edge emission intensity of the manufactured semiconductor nanoparticles was about 5.2.

TEM analysis was performed on the manufactured semiconductor nanoparticles, and the results are shown in FIG. 10. The TEM analysis confirmed that the average size of the manufactured particles was 7.78 nm.

### Example 3

The semiconductor nanoparticles were synthesized in the same manner as in Example 1, except for adjusting the amount of the precursors. ICP-AES analysis and photoluminescence analysis were performed on the manufactured semiconductor nanoparticles, and the results were summarized in Table 1 and Table 2.

### Example 4

The semiconductor nanoparticles were synthesized in the same manner as in Example 1, except for adjusting the amount of the precursors. ICP-AES analysis and photoluminescence analysis were performed on the manufactured semiconductor nanoparticles, and the results were summarized in Table 1 and Table 2.

### Example 5

The first semiconductor nanocrystals were obtained in the same manner as in Example 1.

The semiconductor nanoparticles were synthesized in the same manner as in Example 1, except that 6.8 mL of a 0.06 M solution obtained by dissolving silver acetate in oleylamine was added to the reaction system along with the gallium precursor.

ICP-AES analysis and photoluminescence analysis were performed on the manufactured semiconductor nanoparticles, and the results were summarized in Table 1 and Table 2.

### Example 6

A 2 M selenium precursor solution was prepared by dispersing selenium in trioctylphosphine (TOP).

In a 100 mL reaction flask, octadecene (ODE), silver acetate, indium acetate, and dimethylthiourea (DMTU) were added and vacuum-treated at room temperature for 10 minutes. Subsequently, the nitrogen was flowed into the reaction flask, and oleylamine and dodecanethiol were added. The obtained mixture was heated at 40° C. for 5 minutes, then raised to 260° C., and after 5 minutes, the selenium precursor was added and reacted for about 30 minutes. The temperature of the reaction flask was lowered to 180° C., TOP was added, and the mixture was cooled to room temperature. A nonsolvent was added to the obtained mixture to promote precipitation of the first semiconductor nanocrystals. The obtained first semiconductor nanocrystals were recovered by centrifugation and redispersed in toluene. The amounts of the indium precursor, dimethylthiourea, and selenium precursor relative to 1 mole of the silver precursor were 1.3 moles, 4.6 moles, and 2.3 moles, respectively.

The semiconductor nanoparticles were synthesized in the same manner as in Example 1, except for using the first semiconductor nanocrystals synthesized in this Example 6.

ICP-AES analysis and UV-Vis absorption spectroscopy were performed on the manufactured semiconductor nanoparticles, and the results were summarized in Table 1 and FIG. 8. It was confirmed that the absorption ratio at 550 nm relative to 350 nm was 0.23.

Photoluminescence analysis was performed on the manufactured semiconductor nanoparticles. The semiconductor nanoparticles can emit light with an emission peak wavelength of 596 nm or more. It was confirmed that the full width at half maximum (FWHM) of the light was about 52 nm. It was confirmed that the quantum efficiency of the manufactured semiconductor nanoparticles was greater than or equal to about 30%.

TABLE 1

| | ICP-AES mole ratio | | | | |
|---|---|---|---|---|---|
| | | | | (In + | |
| | S:In | Ag:In | Ga:In | Ga):Ag | Se:In |
| First semiconductor | 1.7:1 | 0.4:1 | — | — | — |
| nanocrystal | | | | | |
| (Example 1) | | | | | |
| First semiconductor | 2.88:1 | 0.7:1 | — | 1.424:1 | 0.09:1 |
| nanocrystal | | | | | |
| (Example 6) | | | | | |
| Example 1 | 3.69:1 | 1.23:1 | 2.68:1 | 2.996:1 | |
| Example 2 | 5.20:1 | 1.82:1 | 2.86:1 | 2.125:1 | |
| Example 3 | 3.48:1 | 1.414:1 | 1.208:1 | 1.561:1 | |
| Example 4 | 4.23:1 | 1.528:1 | 2.123:1 | 2.044:1 | |
| Example 5 | 3.76:1 | 1.188:1 | 1.124:1 | 1.788:1 | |
| Example 6 | 3.43:1 | 0.94:1 | 1.26:1 | 2.414:1 | 0.05:1 |

TABLE 2

| | | | | Ratio of |
|---|---|---|---|---|
| | Peak | Full | Optical | absorption |
| | emission | width | density | at 550 nm to |
| | wavelength | at half | per gram | absorption at |
| | of red light | maximum | (mL*mg⁻¹*cm⁻¹) | 350 nm |
| Example 1 | 626 nm | 49 nm | 2.14 | 0.25 |
| Example 2 | 608 nm | 47 nm | — | 0.15 |
| Example 3 | 606 nm | 50 nm | — | — |
| Example 4 | 607 nm | 42 nm | — | — |
| Example 5 | 622 nm | 60 nm | — | — |

From the results of Table 2 and FIG. 8, it was confirmed that the semiconductor nanoparticles of the examples can emit red light with a relatively narrow full width at half maximum (FWHM) and exhibit improved absorption characteristics for incident light (e.g., blue light).

While this disclosure has been described in connection with what is presently considered to be practical embodiments, it is to be understood that the present subject matter is not limited to the disclosed exemplary embodiments, On the contrary, it is intended to cover various modifications and equivalent arrangements included within the spirit and scope of the appended claims.

What is claimed is:

1. A semiconductor nanoparticle, comprising:
silver, indium, gallium, and sulfur, wherein the semiconductor nanoparticle is substantially free of copper;
wherein a mole ratio of gallium to indium in the semiconductor nanoparticle is greater than or equal to about 0.8:1 and less than or equal to about 20:1;
wherein the semiconductor nanoparticle is configured to emit a red light having a peak emission wavelength of greater than or equal to about 600 nanometers and less than or equal to about 650 nanometers and having a full width at half maximum of greater than or equal to about 5 nanometers and less than or equal to about 90 nanometers.

2. The semiconductor nanoparticle of claim 1, wherein
the red light has the full width at half maximum of greater than or equal to about 10 nanometers and less than or equal to about 50 nanometers.

3. The semiconductor nanoparticle of claim 1, comprising:
a first semiconductor nanocrystal comprising silver, indium, sulfur, and optionally selenium; and
a second semiconductor nanocrystal comprising gallium, sulfur, and optionally silver.

4. The semiconductor nanoparticle of claim 3, wherein
the semiconductor nanoparticle has a core-shell structure, comprising:
a core comprising the first semiconductor nanocrystal; and
a shell comprising the second semiconductor nanocrystal and optionally further comprising selenium, and being disposed on the core.

5. The semiconductor nanoparticle of claim 1, wherein
in the semiconductor nanoparticle,
a mole ratio of gallium to indium is greater than or equal to about 1:1 and less than or equal to about 10:1, and optionally, a mole ratio of a sum of indium and gallium to sulfur is greater than or equal to about 0.65:1 and less than or equal to about 1.5:1.

6. The semiconductor nanoparticle of claim 1, wherein
in the semiconductor nanoparticle, a mole ratio of gallium to indium is greater than or equal to about 2.1:1 and less than or equal to about 3.5:1, or the mole ratio of silver to indium is greater than or equal to about 0.5:1 and less than or equal to about 2.5:1.

7. The semiconductor nanoparticle of claim 1, wherein
in the semiconductor nanoparticle,
a mole ratio of silver to indium is greater than or equal to about 1:1 and less than or equal to about 2:1, and
optionally wherein a mole ratio of gallium to silver is greater than or equal to about 1.8:1 and less than or equal to about 1.65:1.

8. The semiconductor nanoparticle of claim 1, wherein
in the semiconductor nanoparticle, a mole ratio of gallium to sulfur is greater than or equal to about 0.37:1 and less than or equal to about 1:1.

9. The semiconductor nanoparticle of claim 1, wherein
in the semiconductor nanoparticle, the mole ratio of sulfur to indium is greater than or equal to about 3.2:1 and less than or equal to about 10:1.

10. The semiconductor nanoparticle of claim 1, wherein
in the semiconductor nanoparticle, an indium concentration of an inner portion of the semiconductor nanoparticle is greater than that of an outer portion of the semiconductor nanoparticle.

11. The semiconductor nanoparticle of claim 1, wherein
the semiconductor nanoparticle exhibits a peak emission wavelength of red light of greater than or equal to about 603 nanometers and less than or equal to about 645 nanometers, and a quantum yield of greater than or equal to about 30%.

12. The semiconductor nanoparticle of claim 1, wherein
in ultraviolet-visible absorption spectroscopy,
the semiconductor nanoparticle exhibits an optical density at 450 nanometers per gram that is greater than or equal to about 0.8 milliliters per milligram per centimeter or
a ratio of absorption at 550 nanometers relative to absorption at 350 nanometers that is greater than or equal to about 0.05:1.

13. The semiconductor nanoparticle of claim 1, wherein
in ultraviolet-visible absorption spectroscopy,
the semiconductor nanoparticle has an optical density at 450 nanometers per gram that is greater than or equal to about 1 mL*mg⁻¹*cm⁻¹ or
an absorption ratio at 550 nanometers relative to 350 nanometers that is greater than or equal to about 0.2:1 and less than or equal to about 0.8:1.

14. A method of preparing the semiconductor nanoparticle of claim 1, comprising:
contacting a silver precursor, a first sulfur precursor, and an indium precursor in a first reaction medium, comprising a first organic solvent;
heating the first reaction medium to a reaction temperature to prepare a first semiconductor nanocrystal, comprising silver, indium, and sulfur; and
contacting a second sulfur precursor, the first semiconductor nanocrystal, and a gallium precursor in a second reaction medium, comprising a second organic solvent;
wherein an amount of the first sulfur precursor is greater than or equal to about 2.5 moles and less than or equal to about 20 moles per mole of the indium precursor.

15. The method of claim 14, wherein an amount of the first sulfur precursor is greater than or equal to about 4 moles and less than or equal to about 10 moles per mole of the indium precursor.

16. The method of claim 14, wherein the reaction temperature is greater than about 210° C. and less than or equal to about 300° C.

17. An ink composition, comprising:
the semiconductor nanoparticle of claim 1, and a liquid vehicle.

18. A semiconductor nanoparticle composite, comprising: a matrix, and the semiconductor nanoparticle of claim 1 dispersed in the matrix.

19. A color conversion structure, comprising:
a color conversion layer, comprising a color conversion region,
wherein the color conversion region comprises a first region, comprising the semiconductor nanoparticle of claim 1, corresponding to a first pixel; and,
optionally, partition walls defining each region of the color conversion layer.

20. An electronic device, comprising the semiconductor nanoparticle of claim 1.
